(19) United States
(12) Patent Application Publication
(10) Pub. No.: US 2026/0120648 A1
(43) Pub. Date: Apr. 30, 2026

(54) DISPLAY APPARATUS

(71) Applicant: LG Display Co., Ltd., Seoul (KR)

(72) Inventors: Soon-Sung AHN, Paju-si (KR); Jin-Ho LIM, Paju-si (KR)

(73) Assignee: LG Display Co., Ltd., Seoul (KR)

(21) Appl. No.: 19/313,168

(22) Filed: Aug. 28, 2025

(30) Foreign Application Priority Data
Oct. 24, 2024 (KR) 10-2024-0146487

(51) Int. Cl. G09G 3/3266

(52) U.S. Cl. CPC G09G 3/3266; G09G 2310/0245; G09G 2310/061; G09G 2310/08; G09G 2330/021

(57) ABSTRACT

A display apparatus includes: a display panel including a pixel; a light emitting diode and a plurality of transistors electrically connected to the light emitting diode, in the pixel; and a gate driving circuit including a stage that outputs a gate signal to one of the plurality of transistors, wherein the stage includes: a pull-up transistor and a pull-down transistor, a gate electrode of the pull-up transistor and a gate electrode of the pull-down transistor respectively connected to a Q node and a QB node; a transfer transistor connected between the Q node and a Q2 node; and a reset circuit connected to the Q node or the Q2 node, wherein the reset circuit includes an N-type reset transistor receiving a gate high voltage, and a P-type auxiliary transistor connected between the N-type reset transistor and the Q node or the Q2 node.

### CROSS REFERENCE TO RELATED APPLICATIONS

The present application claims the priority benefit of Korean Patent Application No. 10-2024-0146487 filed in Republic of Korea on October 24, 2024, which is hereby incorporated by reference in its entirety for all purposes as if fully set forth herein.

### BACKGROUND

### TECHNICAL FIELD

The present disclosure relates to a driving circuit and a display apparatus.

### DESCRIPTION OF THE RELATED ART

As the information society develops, a demand for display apparatuses for displaying images have increased in various forms, and in recent years, various flat display apparatuses such as organic light emitting display apparatuses and liquid crystal display apparatuses have been used.

A gate driving circuit of the organic light emitting display apparatus is equipped with a reset transistor for reset operation. However, an off-leakage current may occur through the reset transistor.

If the off-leakage current occurs through the reset transistor, a voltage of a node in the gate driving circuit is not maintained normally, which causes a problem in which the gate driving circuit malfunctions.

### BRIEF SUMMARY

The present disclosure provides a driving circuit and a display apparatus that can prevent an off-leakage current of a reset transistor of a gate driving circuit, thus stably maintain a voltage of a node in the gate driving circuit, and thus prevent malfunction of the gate driving circuit.

Additional features and characteristics of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

As embodied and broadly described herein, a display apparatus includes: a display panel including a pixel; a light emitting diode and a plurality of transistors electrically connected to the light emitting diode, in the pixel; and a gate driving circuit including a stage that outputs a gate signal to one of the plurality of transistors, wherein the stage includes: a pull-up transistor and a pull-down transistor, a gate electrode of the pull-up transistor and a gate electrode of the pull-down transistor respectively connected to a Q node and a QB node; a transfer transistor connected between the Q node and a Q2 node; and a reset circuit connected to the Q node or the Q2 node, wherein the reset circuit includes an N-type reset transistor receiving a gate high voltage, and a P-type auxiliary transistor connected between the N-type reset transistor and the Q node or the Q2 node.

In another aspect, a driving circuit includes: a transistor having a source electrode or a drain electrode connected to a node; and a reset circuit connected to the node, wherein the reset circuit includes: an N-type reset transistor receiving a gate high voltage; and a P-type auxiliary transistor connected between the N-type reset transistor and the node.

It is to be understood that both the foregoing general description and the following detailed description are exemplary and explanatory and are intended to provide further explanation of the disclosure and claims.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view schematically illustrating a display apparatus according to a first embodiment of the present disclosure;

FIG. 2 is a circuit view schematically illustrating an example of a pixel according to a first embodiment of the present disclosure;

FIG. 3 is a view illustrating a configuration of a gate driving portion of a display apparatus according to a first embodiment of the present disclosure;

FIGS. 4 and 5 are timing charts schematically illustrating an example of driving signals output from a gate driving portion according to a first embodiment of the present disclosure;

FIG. 6 is a cross-sectional view schematically illustrating an example of a cross-sectional structure of a display panel according to a first embodiment of the present disclosure;

FIG. 7 is a view schematically illustrating a structure of a reset circuit according to a first embodiment of the present disclosure;

FIGS. 8 and 9 are views schematically illustrating operation of a reset circuit according to a first embodiment of the present disclosure;

FIG. 10 is a view schematically illustrating an example of a structure of a scan driving circuit to which a reset circuit of FIG. 7 is applied;

FIG. 11 is a view schematically illustrating an example of a structure of a scan driving circuit to which a reset circuit is applied according to a second embodiment of the present disclosure;

FIG. 12 is a view schematically illustrating a first example of a structure of a scan driving circuit to which a reset circuit is applied according to a third embodiment of the present disclosure;

FIG. 13 is a view schematically illustrating a second example of a structure of a scan driving circuit to which a reset circuit is applied according to a third embodiment of the present disclosure;

FIG. 14 is a view schematically illustrating a first example of a structure of a scan driving circuit to which a reset circuit is applied according to a fourth embodiment of the present disclosure;

FIG. 15 is a view schematically illustrating a second example of a structure of a scan driving circuit to which a reset circuit is applied according to a fourth embodiment of the present disclosure;

FIG. 16 is a view schematically illustrating a first example of a structure of a scan driving circuit to which a reset circuit is applied according to a fifth embodiment of the present disclosure; and

FIG. 17 is a view schematically illustrating a second example of a structure of a scan driving circuit to which a reset circuit is applied according to a fifth embodiment of the present disclosure.

### DETAILED DESCRIPTION

Advantages and features of the present disclosure and methods of achieving them will be apparent with reference to the embodiments described below in detail with the accompanying drawings. However, the present disclosure is not limited to the embodiments disclosed below, but can be realized in a variety of different forms, and these embodiments are provided only to allow the present disclosure to be complete. The present disclosure is provided to fully inform the scope of the disclosure to the skilled in the art of the present disclosure.

The shapes, sizes, proportions, angles, numbers, and the like disclosed in the drawings for explaining the embodiments of the present disclosure are illustrative, and the present disclosure is not limited to the illustrated matters. The same reference numerals refer to the same components throughout the description.

Furthermore, in describing the present disclosure, if it is determined that a detailed description of the related known technology unnecessarily obscure the subject matter of the present disclosure, the detailed description thereof can be omitted. When ‘comprising,’ ‘including,’ ‘having,’ ‘containing,’ and the like are used in this disclosure, other parts can be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on,’ ‘over,’ ‘above,’ ‘below,’ ‘beside,’ ‘under,’ and the like, one or more other parts can be positioned between such two parts unless ‘right’ or ‘directly’ is used.

In the case of a description of a temporal relationship, for example, when a temporal precedence is described as ‘after,’ ‘following,’ ‘before,’ and the like, cases that are not continuous can be included unless ‘directly’ or ‘immediately’ is used.

In describing components of the present disclosure, terms such as first, second and the like can be used. These terms are only for distinguishing the components from other components, and an essence, order, sequence, or number of the components is not limited by the terms.

Respective features of various embodiments of the present disclosure can be partially or wholly connected to or combined with each other and can be technically interlocked and driven variously, and respective embodiments can be independently implemented from each other or can be implemented together with a related relationship.

Hereinafter, embodiments of the present disclosure are described in detail with reference to the drawings. Meanwhile, in the following embodiments, the same and like reference numerals are assigned to the same and like components, and detailed descriptions thereof can be omitted.

### First Embodiment

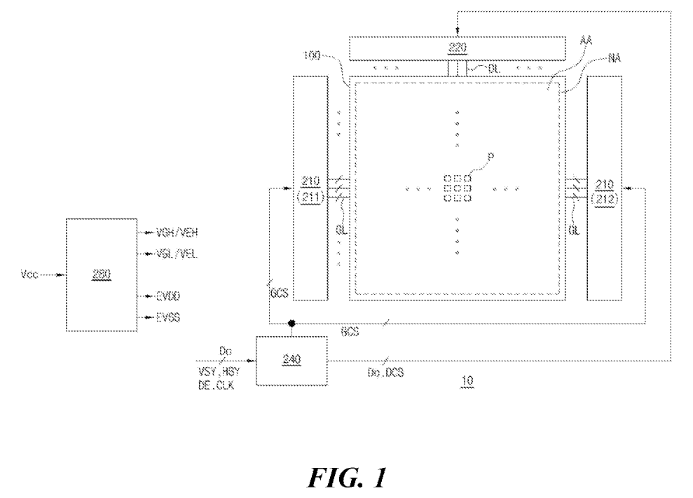

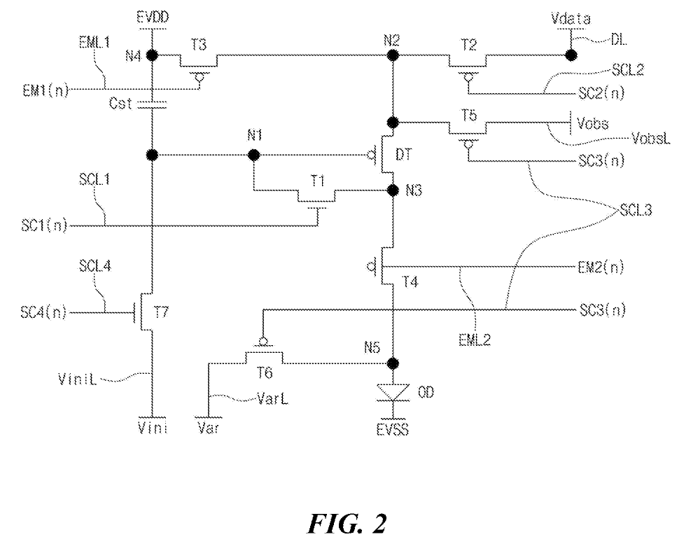

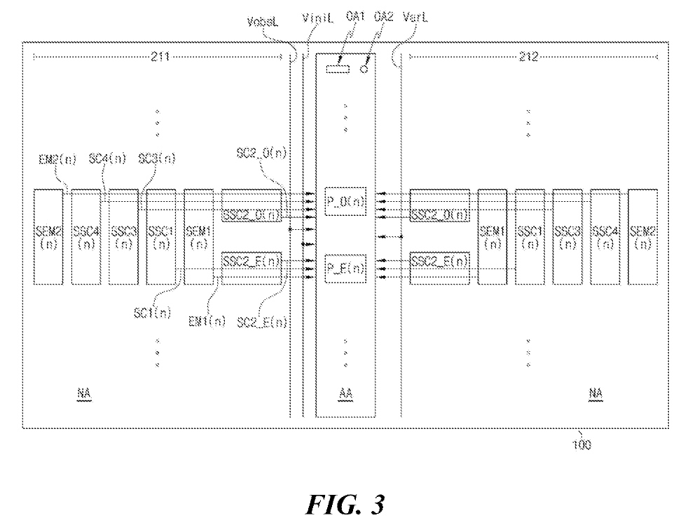

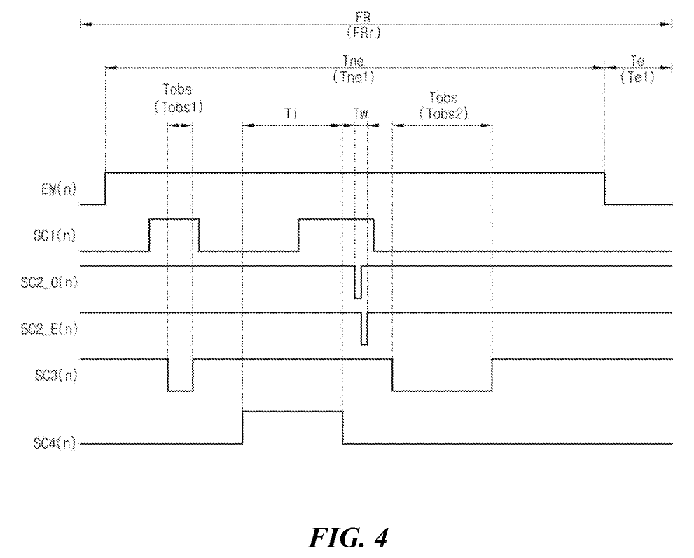

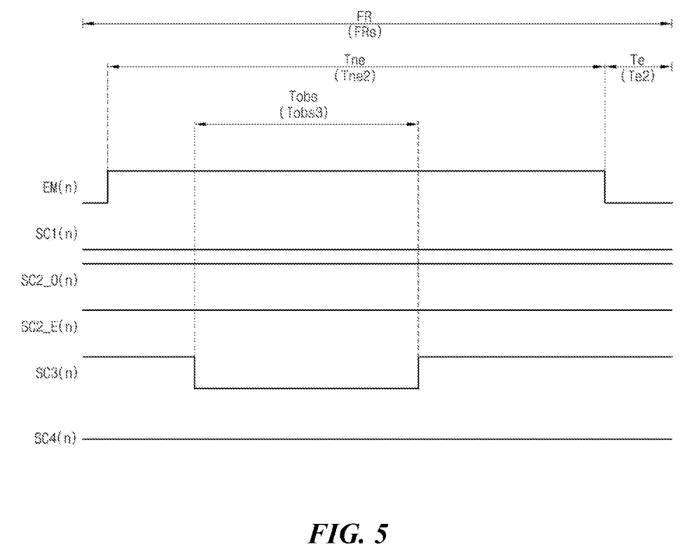

FIG. 1 is a view schematically illustrating a display apparatus according to a first embodiment of the present disclosure. FIG. 2 is a circuit view schematically illustrating an example of a pixel according to a first embodiment of the present disclosure. FIG. 3 is a view illustrating a configuration of a gate driving portion of a display apparatus according to a first embodiment of the present disclosure. FIGS. 4 and 5 are timing charts schematically illustrating an example of driving signals output from a gate driving portion according to a first embodiment of the present disclosure. FIG. 4 illustrates driving signals output during a refresh frame in a VRR method of a first embodiment of the present disclosure, and FIG. 5 illustrates driving signals output during a skip frame in a VRR method of a first embodiment of the present disclosure.

Prior to a specific description, the display apparatus 10 according to this embodiment can include a light emitting display apparatus equipped with a light emitting diode. Furthermore, the display apparatus 10 of this embodiment can include all types of display apparatuses to which a VRR (variable refresh rate) method is applied.

Meanwhile, for convenience of explanation, in this embodiment, an organic light emitting display apparatus is described as an example of the display apparatus 10.

Referring to FIGS. 1 to 5, the display apparatus 10 of this embodiment can include a display panel 100 and a driving circuit portion that drives the display panel 100.

Here, the driving circuit portion can include, for example, a gate driving portion (or gate driving circuit) 210, a data driving portion (or data driving circuit) 220, and a timing control portion (or timing control circuit) 240. In addition, the driving circuit portion can include a power supply portion (or power supply circuit) 280 that supplies power required for driving the display panel 100, the gate driving portion 210, the data driving portion 220, and the timing control portion 240.

The display panel 100 can include a display region AA that displays an image, and a non-display region NA arranged outside the display region AA (or surrounding the display region AA).

In the display region AA, a plurality of pixels P can be arranged in a matrix form along a plurality of horizontal lines (or row lines) and a plurality of vertical lines (or column lines).

Here, the plurality of pixels P can include pixels that display different colors, for example, red, green, and blue pixels that display red, green, and blue, respectively, but not limited thereto.

In the display panel 100, various signal lines that transmit driving signals for driving the pixels P can be formed on a substrate.

In this regard, for example, a plurality of data lines DL that transmit data signals (or data voltages) which are image signals can extend in the vertical direction and be connected to the pixels P of the respective vertical lines.

In addition, a gate line GL that transmits a gate signal (or gate voltage) can extend in the horizontal direction and be connected to the pixel P of the corresponding horizontal line.

In this embodiment, a plurality of gate signals can be used to drive each pixel P, for example, a first scan signal SC1 to a fourth scan signal SC4 and an emission control signal EM can be used. Accordingly, a plurality of gate lines GL respectively transmitting the plurality of gate signals can be used, for example, a first scan line SCL1 to a fourth scan line SCL4 and an emission control line EML can be used.

As such, the plurality of pixels P can be defined by the plurality of data lines DL and gate lines GL intersecting each other.

Each pixel P can include a light emitting diode OD as a light emitting element, and a plurality of transistors and at least one capacitor for driving the light emitting diode OD.

Meanwhile, in this embodiment, for convenience of explanation, an 8T1C structure in which the pixel P is equipped with eight transistors T1 to T7 and DT and one capacitor Cst as illustrated in FIG. 2 is taken as an example.

Referring to FIG. 2, the pixel P can include a plurality of switching transistors, for example, first transistor T1 to seventh transistor T7, a driving transistor DT, a storage capacitor Cst, and the light emitting diode OD.

Each of the first to seventh transistors T1 to T7 and the driving transistor DT can include a first electrode, a second electrode, and a gate electrode. One of the first electrode and the second electrode can be a source electrode, and the other of the first electrode and the second electrode can be a drain electrode.

Each of the first to seventh transistors T1 to T7 and the driving transistor DT can be a P-type or N-type transistor. Meanwhile, in FIG. 2, the second, third, fourth, fifth, and sixth transistors T2, T3, T4, T5, and T6 are configured as P-type transistors, the first and seventh transistors T1 and T7 are configured as N-type transistors, and the driving transistor DT is configured as a P-type transistor, but not limited thereto. Alternatively, the driving transistor DT can be configured as an N-type transistor.

The first transistor T1 to the seventh transistor T7 and the driving transistor DT can include semiconductors of the same material or can include semiconductors of different materials. In this regard, for example, some of the first transistor T1 to the seventh transistor T7 and the driving transistors DT can have one semiconductor layer among a polycrystalline silicon layer, an oxide semiconductor layer, and an amorphous silicon layer, and another some of the first transistor T1 to the seventh transistor T7 and the driving transistors DT can have another semiconductor layer among a polycrystalline silicon layer, an oxide semiconductor layer, and an amorphous silicon layer.

Meanwhile, since an oxide semiconductor has excellent off-current characteristics and has characteristics suitable for a switching transistor, at least one of the first transistor T1 to the seventh transistor T7 can have an oxide semiconductor layer. In addition, since a polycrystalline silicon has excellent mobility, the driving transistor DT can have a polycrystalline silicon layer. In another form, the first transistor T1 to the seventh transistor T7 and the driving transistor DT can be configured, for example, the driving transistor DT can have an oxide semiconductor layer.

Meanwhile, in this embodiment, a case where the first and seventh transistors T1 and T7 include oxide semiconductor layers and the remaining transistors T2 to T6 and DT include polycrystalline silicon layers is taken as an example.

The gate signals provided to a n-th horizontal line of FIG. 2 (more specifically, at least one of an odd horizontal line and an even horizontal line constituting the n-th horizontal line) can be provided from a corresponding n-th stage of the gate driving portion 210. For example, four scan signals, first to fourth scan signals (SC1 to SC4: SC1(n) to SC4(n)) and two emission control signals, first and second emission control signals (EM: EM1(n) and EM2(n)) can be provided. In this case, in the display region AA, first to fourth scan lines SCL1 to SCL4 and first and second emission control lines EML1 and EML2 that are connected to the n-th stage and transmit the first to fourth scan signals SC1(n) to SC4(n) and the first and second emission control signals EM1(n) and EM2(n) to the pixel P can be arranged. Alternatively, the gate driving portion 210 can be configured to provide one emission control signal instead of the two emission control signals EM1(n) and EM2(n).

The first transistor T1 can function as a sampling transistor, the second transistor T2 can function as a data supply transistor, the third and fourth transistors T3 and T4 can function as emission control transistors, the fifth transistor T5 can function as a bias transistor, the sixth transistor T6 can function as a reset transistor (or a first initialization transistor), and the seventh transistor T7 can function as an initialization transistor (or a second initialization transistor).

The light emitting diode OD can include an anode electrode and a cathode electrode. The anode electrode of the light emitting diode OD can be connected to a fifth node N5, and the cathode electrode of the light emitting diode OD can be applied with a low-potential driving voltage EVSS.

The driving transistor DT can include a first electrode connected to a second node N2, a second electrode connected to a third node N3, and a gate electrode connected to a first node N1. The driving transistor DT can provide a driving current to the light emitting diode OD based on a voltage of the first node N1 (i.e., the data voltage Vdata stored in the storage capacitor Cst).

The first transistor T1 can include a first electrode connected to the first node N1, a second electrode connected to the third node N3, and a gate electrode receiving the first scan signal SC1(n). The first transistor T1 can be turned on in response to the first scan signal SC1(n), and the data voltage Vdata can be applied (or written or sampled) to the gate electrode of the driving transistor DT.

The storage capacitor Cst can be connected between the first node N1 and a fourth node N4. The storage capacitor Cst can store or maintain a high-potential driving voltage EVDD.

The second transistor T2 can include a first electrode connected to the data line DL (or, receiving the data voltage Vdata), a second electrode connected to the second node N2, and a gate electrode receiving the second scan signal SC2(n). The second transistor T2 can be turned on in response to the second scan signal SC2(n) and transmit the data voltage Vdata to the second node N2.

The third transistor T3 and the fourth transistor T4 (or first and second emission control transistors) can be connected between a power line of the high-potential driving voltage EVDD and the light emitting diode OD, and can form a current path along which the driving current generated by the driving transistor DT moves.

The third transistor T3 can include a first electrode connected to the fourth node N4 and receiving the high-potential driving voltage EVDD, a second electrode connected to the second node N2, and a gate electrode receiving the first emission control signal EM1(n).

The fourth transistor T4 can include a first electrode connected to the third node N3, a second electrode connected to the fifth node N5 (or the anode electrode of the light emitting diode OD), and a gate electrode receiving the second emission control signal EM2(n).

The third and fourth transistors T3 and T4 can be turned on in response to the first and second emission control signals EM1(n) and EM2(n), the driving current can be supplied to the light emitting diode OD, and the light emitting diode OD can emit light with a luminance corresponding to the driving current.

The fifth transistor T5 can include a first electrode connected to a bias voltage line VobsL that transmits a bias voltage Vobs, a second electrode connected to the second node N2, and a gate electrode that receives the third scan signal SC3(n).

The sixth transistor T6 can include a first electrode connected to a reset voltage line (or a first initialization voltage line) VarL that transmits an anode reset voltage (or a first initialization voltage) Var, a second electrode connected to the fifth node N5, and a gate electrode that receives the third scan signal SC3(n).

The fifth and sixth transistors T5 and T6 can be turned on in response to the third scan signal SC3(n), the bias voltage Vobs can be applied to the second node N2, and the anode reset voltage Var can be applied to the fifth node N5 (i.e., the anode electrode of the light emitting diode OD).

The seventh transistor T7 can include a first electrode connected to an initialization voltage line ViniL that transmits an initialization voltage Vini, a second electrode connected to the first node N1, and a gate electrode that receives the fourth scan signal SC4(n).

The seventh transistor T7 can be turned on in response to the fourth scan signal SC4(n) and can apply the initialization voltage Vini to initialize the gate electrode of the driving transistor DT. Unnecessary charges can remain in the gate electrode of the driving transistor DT due to the high-potential driving voltage EVDD applied to the storage capacitor Cst. Thus, by applying the initialization voltage Vini to the gate electrode of the driving transistor DT through the seventh transistor T7, the remaining charges can be initialized.

The 8T1C structure of the pixel P described above is an example, and the pixel P of this embodiment can be configured with a different structure.

Referring to FIG. 1, the timing control portion 240 can process image data Do input from a host system to be suitable for size and resolution of the display panel 100 and supply them to the data driving portion 220. The timing control portion 240 can generate a gate control signal GCS and a data control signal DCS using synchronization signals input from the host system, for example, a dot clock signal CLK, a data enable signal DE, a horizontal synchronization signal HSY, and a vertical synchronization signal VSY. By supplying the gate control signal GCS and the data control signal DCS generated in this way to the gate driving portion 210 and the data driving portion 220, respectively, the gate driving portion 210 and the data driving portion 220 can be controlled.

The timing control portion 240 can be configured to be combined with various processors, for example, a microprocessor, a mobile processor, an application processor, etc., depending on a device to be mounted.

Meanwhile, the host system can be, for example, a driving system that drives an electronic device to which the display apparatus 10 is applied. The electronic device can be, for example, one of a TV (Television), a navigation system, a monitor, a mobile device, and a wearable device.

The gate driving portion 210 can receive the gate control signal GCS from the timing control portion 240, generate the gate signals, and sequentially apply the gate signals to the gate lines GL. For example, the gate signals can be sequentially output from the top to the bottom in the vertical direction.

The gate driving portion 210 can be arranged, for example, on at least one side of the display region AA. In this embodiment, a case is taken as an example in which the gate driving portion 210 is configured to include first and second gate driving portions 211 and 212 arranged on both sides of the display region AA, for example, on the left and right sides of the display region AA.

The gate driving portion 210 can be formed directly in the non-display region NA on the substrate of the display panel 100, for example, in a GIP (gate-in panel) structure. In this case, the gate driving portion 210 can be formed during processes of forming elements of the display panel 100.

The gate driving portion 210 configured with the GIP structure can include, for example, a first scan driving circuit that sequentially outputs the first scan signals SC1, a second scan driving circuit that sequentially outputs the second scan signals SC2, a third scan driving circuit that sequentially outputs the third scan signals SC3, a fourth scan driving circuit that sequentially outputs the fourth scan signal SC4, a first emission driving circuit that sequentially outputs the first emission control signals EM1, and a second emission driving circuit that sequentially outputs the second emission control signals EM2.

Each of the first scan driving circuit to the fourth scan driving circuit and the first and second emission driving circuits can be configured with a shift register including a plurality of stages that output respective signals. The gate driving portion 210 can include a stage configured to output a gate signal to one of the plurality of transistors electrically connected to the light emitting diode OD.

The gate driving portion 210 is described with further reference to FIG. 3. FIG. 3 illustrates a part of the gate driving portion 210, and for convenience of explanation, a configuration of a portion of the gate driving portion 210 that drives the n-th horizontal line configured with a n-th odd horizontal line (or 2n-1-th horizontal line) and a n-th even horizontal line (or 2n-th horizontal line) of the display region AA is illustrated.

In the first gate driving portion 211 of the gate driving portion 210, for example, first, third, and fourth scan stages SSC1(n), SSC3(n), and SSC4(n) that constitute the first, third, and fourth scan driving circuits, respectively, first and second emission stages SEM1(n) and SEM2(n) that constitute the first and second emission driving circuits, respectively, and odd and even second scan stages SSC2_O(n) and SSC2_E(n) that constitute the second scan driving circuit can be arranged.

In addition, in the second gate driving portion 212 of the gate driving portion 210, for example, the first, third, and fourth scan stages SSC1(n), SSC3(n), and SSC4(n) that constitute the first, third, and fourth scan driving circuits, respectively, the first and second emission stages SEM1(n) and SEM2(n) that constitute the first and second emission driving circuits, respectively, and the odd and even second scan stages SSC2_O(n) and SSC2_E(n) that constitute the second scan driving circuit can be arranged.

In the gate driving portion 210, the odd and even second scan stages SSC2_O(n) and SSC2_E(n) constituting the second scan driving circuit can be arranged so as to be closest to the display region AA, and the second emission stage SEM2(n) can be arranged at the outermost part farthest from the display region AA. In addition, the first emission stage SEM1(n) can be arranged between the first to fourth scan stages SSC1(n) to SSC4(n).

The arrangement of the first to fourth scan stages SSC1(n) to SSC4(n) and the first and second emission stages SEM1(n) and SEM2(n) shown in FIG. 3 is an example, and they can be arranged in various combinations in the first and second gate driving portions 211 and 212.

The first scan stage SSC1(n) can generate the first scan signal SC1(n) and output it to the corresponding first scan line SCL1. Accordingly, the pixel P_O(n) of the n-th odd horizontal line and the pixel P_E(n) of the n-th even horizontal line can be commonly applied with the first scan signal SC1(n).

The odd second scan stage SSC2_O(n) can generate an odd second scan signal SC2_O(n) and output it to the corresponding odd second scan line SCL2, and the even second scan stage SSC2_E(n) can generate an even second scan signal SC2_E(n) and output it to the corresponding even second scan line SCL2. Accordingly, the pixel P_O(n) of the n-th odd horizontal line can be applied with the odd second scan signal SC2_O(n), and the pixel P_E(n) of the n-th even horizontal line can be applied with the even second scan signal SC2_E(n). Here, the odd second scan signal SC2_O(n) and the even second scan signal SC2_E(n) can have different timings. For example, the odd second scan signal SC2_O(n) and the even second scan signal SC2_E(n) can be applied to a data writing period of the n-th odd horizontal line and a data writing period of the n-th even horizontal line immediately following it, respectively.

The third scan stage SSC3(n) can generate the third scan signal SC3(n) and output it to the corresponding third scan line SCL3. Accordingly, the pixels P_O(n) and P_E(n) of the n-th odd and even horizontal lines can be commonly applied with the third scan signal SC3(n).

The fourth scan stage SSC4(n) can generate the fourth scan signal SC4(n) and output it to the corresponding fourth scan line SCL4. Accordingly, the pixels P_O(n) and P_E(n) of the n-th odd and even horizontal lines can be commonly applied with the fourth scan signal SC4(n).

The first emission stage SEM1(n) can generate the first emission control signal EM1(n) and output it to the corresponding first emission control line EML1. Accordingly, the pixels P_O(n) and P_E(n) of the n-th odd and even horizontal lines can be commonly applied with the first emission control signal EM1(n).

The second emission stage SEM2(n) can generate the second emission control signal EM2(n) and output it to the corresponding second emission control line EML2. Accordingly, the pixels P_O(n) and P_E(n) of the n-th odd and even horizontal lines can be commonly applied with the second emission control signal EM2(n).

Meanwhile, referring to FIG. 3, the bias voltage line VobsL, the reset voltage line VarL, and the initialization voltage line ViniL can be arranged between the gate driving portion 210 and the display region AA.

The bias voltage line VobsL, the reset voltage line VarL, and the initialization voltage line ViniL can respectively supply the bias voltage Vobs, the anode reset voltage Var, and the initialization voltage Vini from the power supply portion 280 to the pixels P within the display region AA.

In FIG. 3, each of the bias voltage line VobsL, the reset voltage line VarL, and the initialization voltage line ViniL is illustrated as being located only on the left or right side of the display region AA, but not limited thereto, and each of the bias voltage line VobsL, the reset voltage line VarL, and the initialization voltage line ViniL can be located on both sides, and even if located on one side, the location on the left or right side is not limited.

Furthermore, referring to FIG. 3, one or more optical regions OA1 and OA2 can be disposed in the display region AA.

The one or more optical regions OA1 and OA2 can be arranged to overlap one or more optical electronic devices, for example, a photographing device such as a camera (or image sensor), and/or a detection sensor such as a proximity sensor and an illuminance sensor. For the operation of the optical electronic device, the one or more optical regions OA1 and OA2 can have a light-transmitting structure formed therein and can have transmittance of a certain level or higher. In other words, a number of pixels P per unit area in the one or more optical regions OA1 and OA2 can be smaller than a number of pixels P per unit area in a regular region excluding the optical regions OA1 and OA2 in the display region AA. That is, a resolution of the one or more optical regions OA1 and OA2 can be lower than a resolution of the regular region within the display region AA.

Referring back to FIG. 1, the data driving portion 220 can receive the image data Do and the data control signal DCS from the timing control portion 240, and in response to the data control signal DCS, the data driving portion 220 can convert the image data Do into analog image data, i.e., data voltages Vdata, and outputs them to the respective data lines DL.

The power supply portion 280 can generate DC power required for driving the pixel array and the driving circuit portion of the display panel 100 using, for example, a DC-DC converter. The DC-DC converter can include a charge pump, a regulator, a buck converter, a boost converter, etc.

The power supply portion 280 can receive, for example, a power voltage Vcc that is a driving voltage for driving the display apparatus (10) from the host system, and generate the DC voltages such as the gate low voltages VGL and VEL, the gate high voltages VGH and VEH, the high-potential driving voltage EVDD, and the low-potential driving voltage EVSS. The gate low voltages VGL and VEL and the gate high voltages VGH and VEH can be supplied to the gate driving portion 210. The high-potential driving voltage EVDD and the low-potential driving voltage EVSS can be supplied in common to the pixels P in the display panel 100.

The display apparatus 10 of this embodiment configured as above can be driven at low power in the VRR method in which a refresh cycle (or refresh rate) is adjusted, in order to reduce power consumption.

In this regard, in a normal driving mode which is a high-speed driving mode, the display apparatus 10 can operate to refresh (or update) an image of the display panel 100 (or the data voltage Vdata applied to each pixel P) by frame FR. For example, in the high-speed driving mode, the display apparatus 10 can be driven at a refresh rate of 120 Hz, so that a refresh operation can be performed for 120 frames FR per second. In this way, in the high-speed driving mode, all frames FR can be assigned as refresh frames FRr in which the data voltage Vdata is written.

In the case of displaying a still image, etc., the display apparatus 10 can be driven in a low-speed driving mode. In the low-speed driving mode, the refresh rate is reduced, so that the refresh cycle of the display panel 100 becomes longer. For example, in the case of low-speed driving with a refresh rate of 10 Hz, one refresh frame FRr and 11 consecutive skip frames FRs can be alternately repeated. As such, in the low-speed driving mode, the frames FR can be divided into the refresh frame FRr in which the data voltage Vdata is written and the skip frame FRs in which the data voltage Vdata is not written and the writing is skipped.

As such, in the low-speed driving mode, as the driving frequency decreases, the cycle of the refresh frame FRr (or the interval between the refresh frames FRr) becomes longer, and one or more skip frames FRs exist between the refresh frames FRr.

During the skip frame FRs, the image refresh operation is stopped, so that power consumption can be reduced.

In the refresh frame FRr when the data voltage Vdata is written, the first scan signal SC1 to the fourth scan signal SC4 (more specifically, their scan pulses) can be applied during a non-emission period in order to write the data voltage Vdata to the corresponding pixel P.

In addition, in the skip frames FRs when the data voltage Vdata is not written and maintained, an operation of applying the bias voltage Vobs to alleviate hysteresis of the driving transistor DT and the anode reset voltage Var to reset the anode electrode of the light emitting diode OD can be performed. To this end, the third scan signal SC3 (more specifically, its scan pulse) for providing the bias voltage Vobs and the anode reset voltage Var to the pixel P can be applied.

The driving in the refresh frame FRr and the skip frame FRs of the VRR method can be described with further reference to FIGS. 4 and 5.

Meanwhile, in FIGS. 4 and 5, for convenience of explanation, the first and second emission control signals EM1(n) and EM2(n) are not individually illustrated, but rather one emission control signal EM(n) representing them is illustrated as an example.

First, referring to FIG. 4, the driving in the refresh frame FRr is described. The refresh frame FRr can be divided into a non-emission period Tne and an emission period Te. The non-emission period Tne of the refresh frame FRr can be referred to as a first non-emission period Tne1, and the emission period Te of the refresh frame FRr can be referred to as a first emission period Te1.

The first non-emission period Tne1 and the first emission period Te1 can be defined by the emission control signal EM(n) of the refresh frame FRr. In this regard, a scan pulse section of a high level, as a turn-off level, of the emission control signal EM(n) can correspond to the first non-emission period Tne1, and a section of a low level, as a turn-on level, of the emission control signal EM(n) can correspond to the first emission period Te1.

In the first non-emission period Tne1 of the refresh frame FRr, an operation in which the data voltage Vdata is applied and written can be performed.

In this regard, for example, during the data writing period (or sampling period) Tw when each of the odd and even second scan signals SC2_O(n) and SC2_E(n) is applied, more specifically, a scan pulse of a low level, as a turn-on level, of each of the odd and even second scan signals SC2_O(n) and SC2_E(n) is applied, the data voltage Vdata of each of the odd and even pixels P_O(n) and P_E(n) can be applied and written to the gate electrode of the driving transistor DT. Meanwhile, in the data writing period Tw, a threshold voltage of the driving transistor DT can be sampled and reflected to the gate electrode of the driving transistor DT.

In the data writing period Tw, the first scan signal SC1(n) can have a scan pulse of a high level, which is a turn-on level, so that the first transistor T1 can have a turn-on state.

Meanwhile, in the first non-emission period Tne1, at least one bias period (or anode reset period) Tobs when the bias voltage Vobs and the anode reset voltage Var are applied can be located. In this embodiment, a case where the bias periods Tobs are set before and after the data writing period Tw is taken as an example. In this case, for convenience of explanation, the bias period Tobs set before the data writing can be referred to as a first bias period Tobs1, and the bias period Tobs set after the data writing can be referred to as a second bias period Tobs2.

In each of the first and second bias periods Tobs1 and Tobs2, the third scan signal SC3(n) can have a scan pulse of a low level which is a turn-on level.

In this case, the fifth transistor T5 can be turned on, so that the bias voltage Vobs can be applied to the second node N2 and the third node N3. Through this, an on-bias stress operation for the driving transistor DT can be performed.

In addition, the sixth transistor T6 can be turned on, so that the anode reset voltage Var can be applied to the fifth node N5. Through this, an anode reset operation for the anode electrode of the light emitting diode OD can be performed.

Meanwhile, an operation of applying the initialization voltage Vini can be performed between the data writing period Tw and the first bias period Tobs1. In this initialization period Ti, the fourth scan signal SC4(n) can have a scan pulse of a high level which is a turn-on level. Accordingly, the seventh transistor T7 can be turned on, so that the initialization voltage Vini can be applied to the first node N1, i.e., the gate electrode of the driving transistor DT. Through this, an initialization operation for the driving transistor DT can be performed.

Next, referring to FIG. 5, the driving in the skip frame FRs is described. The skip frame FRs can be divided into a non-emission period Tne and an emission period Te. Here, the non-emission period Tne of the skip frame FRs can be referred to as a second non-emission period Tne2, and the emission period Te of the skip frame FRs can be referred to as a second emission period Te2.

The second non-emission period Tne2 and the second emission period Te2 can be defined by the emission control signal EM(n) of the skip frame FRs. In this regard, a scan pulse section of a high level, as a turn-off level, of the emission control signal EM(n) can correspond to the second non-emission period Tne2, and a section of a low level, as a turn-on level, of the emission control signal EM(n) can correspond to the second emission period Te2.

In the second non-emission period Tne2 of the skip frame FRs, the operation of writing the data voltage Vdata is not performed, so the data writing period Tw within the first non-emission period Tne1 of the refresh frame FRr is not set.

Accordingly, in the second non-emission period Tne2 of the skip frame FRs, the first scan signal SC1(n) related to the data writing operation can maintain a low level, which is a turn-off level, and the second scan signals SC2_O(n) and SC2_E(n) can maintain a high level which is a turn-off level.

In addition, in the second non-emission period Tne2 of the skip frame FRs, the initialization operation of applying the initialization voltage Vini is not performed, so the initialization period Ti within the first non-emission period Tne1 of the refresh frame FRr is not set.

Accordingly, in the second non-emission period Tne2 of the skip frame FRs, the fourth scan signal SC4(n) related to the initialization operation can maintain a low level which is a turn-off level.

Meanwhile, in the second non-emission period Tne2 of the skip frame FRs, a bias period Tobs when the bias voltage Vobs and the anode reset voltage Var are applied can be set. Here, for convenience of explanation, the bias period Tobs set within the second non-emission period Tne2 can be referred to as a third bias period Tobs3.

In the third bias period Tobs3, the third scan signal SC3(n) can have a scan pulse of a low level which is a turn-on level. Accordingly, an on-bias stress operation for the driving transistor DT and the anode reset operation for the anode electrode of the light emitting diode OD can be performed.

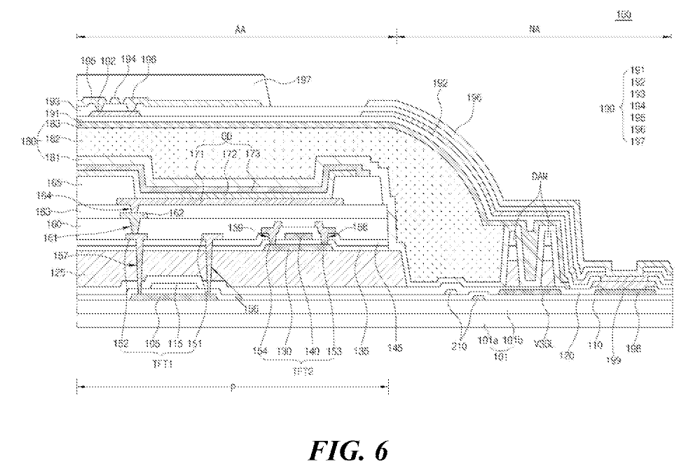

Hereinafter, an example of a cross-sectional structure of the display panel 100 of this embodiment is described with further reference to FIG. 6. FIG. 6 is a cross-sectional view schematically illustrating an example of a cross-sectional structure of a display panel according to a first embodiment of the present disclosure.

In FIG. 6, for convenience of explanation, two thin film transistors TFT1 and TFT2 are illustrated in the pixel P within the display region AA. Here, the thin film transistor TFT1 positioned relatively lower and closer to the substrate 101 is referred to as a first thin film transistor TFT1, which can be a polycrystalline silicon thin film transistor. The thin film transistor TFT2 positioned relatively upper and farther from the substrate 101 is referred to as a second thin film transistor TFT2, which can be an oxide thin film transistor.

Meanwhile, the first thin film transistor TFT1 can be a driving transistor (DT of FIG. 2), but not limited thereto, and in FIG. 6, for convenience of explanation, a case in which the first thin film transistor TFT1 is connected to the light emitting diode OD is illustrated. In addition, the second thin film transistor TFT2 can be one of the first to seventh transistors (T1 to T7 of FIG. 2) that are switching thin film transistors, more specifically, the first transistor T1 connected to the storage capacitor Cst or the seventh transistor T7 connected to the gate electrode of the driving transistor DT, but not limited thereto.

The substrate 101 can be configured as, for example, a thin glass substrate (or glass film) or a plastic substrate (or plastic film) so as to implement a flexible characteristics of the display panel 100.

Here, in a case where the substrate 101 is configured as a glass substrate, for example, the substrate 101 can have a thickness of approximately 0.2 mm.

Meanwhile, in a case where the substrate 101 is configured as a plastic substrate, for example, the substrate 101 can include at least one polyimide layer. In this embodiment, the substrate 101 configured of two polyimide layers, which are a first polyimide layer 101a and a second polyimide layer 101b, is taken as an example.

The first thin film transistor TFT1 can include a first semiconductor layer 105 disposed on the substrate 101, a first gate electrode 115 overlapping the semiconductor layer 105 with a first insulating layer 110 interposed therebetween, and a first source electrode 151 and a first drain electrode 152 located on a fourth insulating layer 145 over the first gate electrode 115. Here, the first semiconductor layer 105 can be formed of polycrystalline silicon, but not limited thereto.

The first semiconductor layer 105 can include a central channel region and source and drain regions on both sides thereof. The first source electrode 151 and the first drain electrode 152 can be connected to the source region and the drain region of the first semiconductor layer 105 through the first and second contact holes 156 and 157 that are formed in the insulating layers 110, 120, 125, 135, and 145 located below the first source electrode 151 and the first drain electrode 152.

A second insulating layer 120 can be formed on the first gate electrode 115 of the first thin film transistor TFT1.

A first interlayered insulating layer 125 can be formed on the second insulating layer 120. The second thin film transistor TFT2 can be formed on the first interlayered insulating layer 125.

The second thin film transistor TFT2 can include a second semiconductor layer 130 on the first interlayered insulating layer 125, a second gate electrode 140 overlapping the second semiconductor layer 130 with a third insulating layer 135 interposed therebetween, and a second source electrode 153 and a second drain electrode 154 located on the fourth insulating layer 145 over the second gate electrode 140. Here, the second semiconductor layer 130 can be formed of an oxide semiconductor, but not limited thereto.

The second semiconductor layer 130 can include a central channel region and source and drain regions on both sides thereof. The second source electrode 153 and the second drain electrode 154 can be connected to the source and drain regions of the second semiconductor layer 130 through third and fourth contact holes 158 and 159 formed in the insulating layers 135 and 145 located below the second source electrode 153 and the second drain electrode 154.

A second interlayered insulating layer (or first planarization layer) 160 can be formed on the second thin film transistor TFT2.

Here, the first, second, third, and fourth insulating layers 110, 120, 135, and 145 can be formed of an inorganic insulating material such as silicon nitride or silicon oxide, but not limited thereto.

In addition, the first and second interlayered insulating layers 125 and 160 can be formed of an organic insulating material such as photo acrylic or benzocyclobutene, but not limited thereto.

A connection electrode 162 can be formed on the second interlayered insulating layer 160. The connection electrode 162 can be connected to the first drain electrode 152 through a contact hole 161 formed in the second interlayered insulating layer 160.

A third interlayered insulating layer (or second planarization layer) 163 can be formed on the connection electrode 162. The third interlayered insulating layer 163 can be formed of an organic insulating material such as photo acrylic or benzocyclobutene, but not limited thereto.

The light emitting diode OD and a bank 165 can be formed on the third interlayered insulating layer 163.

The light emitting diode OD can include an anode electrode (or first electrode) 171, a light emitting layer 172, and a cathode electrode (or second electrode) 173.

The anode electrode 171 can be connected to the connection electrode 162 through the contact hole 164 formed in the third interlayered insulating layer 163.

The bank 165 can be disposed along a boundary of the pixel P and can be formed to cover an edge of the anode electrode 171. The light emitting layer 172 can be formed on the anode electrode 171 exposed through an opening of the bank 165.

The cathode electrode 173 can be formed on the light emitting layer 172 and can be applied with the low-potential driving voltage (EVSS of FIG. 2).

An encapsulation layer 180 can be formed on the cathode electrode 173. The encapsulation layer 180 can include at least one inorganic encapsulation layer and at least one organic encapsulation layer, but not limited thereto. In this disclosure, a structure of the encapsulation layer 180, in which a first encapsulation layer 181, a second encapsulation layer 182, and a third encapsulation layer 183 are sequentially stacked, is described as an example.

The first encapsulation layer 181 can be formed on the substrate 101 on which the cathode electrode 173 is formed. The third encapsulation layer 183 can be formed on the substrate 101 on which the second encapsulation layer 182 is formed, and can be formed to surround an upper surface, a lower surface, and a side surface of the second encapsulation layer 182 together with the first encapsulation layer 181. The first encapsulation layer 181 and the third encapsulation layer 183 can minimize or prevent external moisture or oxygen from penetrating into the light emitting diode OD. The first encapsulation layer 181 and the third encapsulation layer 183 can be formed of an inorganic insulating material capable of low-temperature deposition, such as silicon nitride, silicon oxide, silicon oxynitride, or aluminum oxide.

The second encapsulating layer 182 can acts as a buffer to relieve stress between layers due to bending of the display apparatus 10, and can flatten steps between layers. The second encapsulation layer 182 can be formed on the substrate 101 on which the first encapsulation layer 181 is formed, using a non-photosensitive organic insulating material such as acrylic resin, epoxy resin, phenolic resin, polyamide resin, polyimide resin, polyethylene, or silicon oxycarbon (SiOC), or a photosensitive organic insulating material such as photo acrylic, but not limited thereto. When the second encapsulation layer 182 is formed through an inkjet method, a dam DAM can be placed in the non-display region NA to prevent the second encapsulation layer 182 in liquid form from spreading to an edge of the substrate 101. The dam DAM can be disposed closer to the edge of the substrate 101 than the second encapsulation layer 182. By the dam DAM, the second encapsulation layer 182 can be prevented from spreading to a pad region, where a conductive pad is disposed, on an outermost edge of the substrate 101.

The dam DAM can be designed to prevent the spreading of the second encapsulation layer 182, but if the second encapsulation layer 182 is formed to exceed a height of the dam DAM during a process, the second encapsulation layer 182 as an organic layer can be exposed to an outside, so that moisture, etc. can easily penetrate into the light emitting element. To prevent this, 10 or more dam DAM can be formed in succession, but not limited thereto.

The dam DAM can be formed simultaneously with the first interlayered insulating layer 125, the second interlayered insulating layer 160, and the third interlayered insulating layer 163. When forming the first interlayered insulating layer 125, a lower layer of the dam DAM can be formed together, and when forming the second and third interlayered insulating layers 160 and 163, an upper layer of the dam DAM can be formed together, so that the dam DAM can be formed in a triple laminated structure. As another example, the dam DAM can be formed together with one or two of the first, second, and third interlayered insulating layers 125, 160, and 163.

Accordingly, the dam DAM can be formed of the same material as the first interlayered insulating layer 125, the second interlayered insulating layer 160, and the third interlayered insulating layer 163, but not limited thereto.

The dam DAM can be formed to overlap a low-potential driving voltage line VSSL. For example, the low-potential driving voltage line VSSL can be formed at a lower layer of a region, where the dam DAM is located, in the non-display region NA.

The low-potential driving voltage line VSSL and the gate driving portion 210 configured in the GIP structure can be formed along a periphery of the display panel 100, and the low-potential driving voltage line VSSL can be located outside the gate driving portion 210. In addition, the low-potential driving voltage line VSSL can be connected to the cathode electrode 173 to apply the low-potential driving voltage EVSS. The gate driving portion 210 is simply shown in a planar and cross-sectional manner in the drawings, but can be configured with the same structure as the first thin film transistor TFT1 and/or the second thin film transistor TFT2 of the display region AA.

A touch layer (or touch element layer) 190 can be disposed on the encapsulation layer 180. In the touch layer 190, a touch buffer layer 191 can be positioned between a touch sensor metal including touch electrode connection lines 192 and 194 and touch electrodes 195 and 196, and the cathode electrode 173 of the light emitting diode OD.

The touch buffer layer 191 can block a chemical solution (developer, etchant, etc.) used in a manufacturing process of the touch sensor metal disposed on the touch buffer layer 191 or moisture from the outside from penetrating into the light emitting layer 172 containing an organic material. Accordingly, the touch buffer layer 191 can prevent damage to the light emitting layer 172 that is vulnerable to the chemical solution or moisture.

According to a mutual-capacitance-based touch sensor structure, the touch electrodes 195 and 196 can be disposed on the touch buffer layer 191, and the touch electrodes 195 and 196 can be arranged to cross each other.

The touch electrode connection lines 192 and 194 can electrically connect the touch electrodes 195 and 196. One of the touch electrode connection lines 192 and 194, and the touch electrodes 195 and 196 can be located at different layers with a touch insulation layer 193 interposed therebetween. In addition, the other of the touch electrode connection lines 192 and 194 and the touch electrodes 195 and 196 can be located at the same layer on the touch insulation layer 193.

The touch electrode connection lines 192 and 194 can be arranged to overlap the bank 165, thereby preventing decrease in aperture ratio, but not limited thereto.

Meanwhile, a part of the touch electrodes 195 and 196 and a part of the touch electrode connection line 192 can extend along the top and side surfaces of the encapsulation layer 180 and the top and side surfaces of the dam DAM and be electrically connected to a touch driving circuit through a touch pad 198 and 199.

A part of the touch electrodes 195 and 196 and a part of the touch electrode connection line 192 can receive a touch driving signal from the touch driving circuit (i.e., the touch driving signal can be transmitted to the touch electrodes 195 and 196), and can transmit a touch sensing signal detected by the touch electrodes 195 and 196 to the touch driving circuit.

In this regard, for example, a driving IC (e.g., data IC, etc.) of the data driving portion 220 including the touch driving circuit can be configured in a COF type and connected to the non-display region NA of the substrate 101 of the display panel 100, and in this case, an end of the touch pad 198 and 199 can be connected to a flexible circuit film on which the driving IC is mounted, so that a signal can be transmitted.

A touch protective layer 197 can be disposed on the touch electrodes 195 and 196. In the drawing, the touch protective layer 197 is shown as being disposed only on the touch electrodes 195 and 196, but not limited thereto, and the touch protective layer 197 can extend before or after the dam DAM to be disposed on the touch electrode connection line 192.

In addition, a color filter can be disposed on the encapsulation layer 180. The color filter can be positioned on the touch layer 190, or between the encapsulation layer 180 and the touch layer 190.

Meanwhile, the gate driving portion 210 of this embodiment can be equipped with a reset circuit that implements a reset operation.

In this regard, the reset circuit can be equipped, for example, in each stage of a driving circuit that outputs a gate signal. In a blank section between the frames FR, the reset circuit can output a gate high voltage VGH, which is a reset voltage for resetting an output control node of the stage, to reset a Q node of the stage electrically connected to the reset circuit or a Q2 node of the stage electrically connected to the Q node.

The reset circuit can include a reset transistor which is a reset switch that receives the gate high voltage VGH and turns on during a reset period to output the gate high voltage VGH.

The reset transistor can be formed as an N-type oxide transistor including an oxide semiconductor with excellent off-current characteristics. In this regard, the oxide transistor has the advantage of lower off-leakage current compared to a polycrystalline transistor including polycrystalline silicon due to its characteristics, and thus, the oxide transistor can be used as the reset transistor of the reset circuit for stable resetting of the Q node.

However, if a source electrode of the reset transistor is directly connected to the Q node or Q2 node, the Q node or Q2 node may be electrically coupled to a gate clock for outputting the gate signal. In this regard, the Q node or Q2 node may form a parasitic capacitance with a gate electrode of a transistor that is electrically connected thereto and receives the gate clock and thus be electrically coupled to the gate clock.

Due to the electrical coupling, a voltage (Vsn) of the source electrode of the reset transistor may be varied. Because of the electrical coupling, the voltage Vsn of the source electrode of the reset transistor in a turn-off state may be lower than a gate low voltage VGL, and even the voltage Vsn of the source electrode may be equal to or lower than (VGL - Vthn) (where Vthn is a threshold voltage of the reset transistor).

As such, when the voltage Vsn of the source electrode of the reset transistor becomes equal to or lower than (VGL - Vthn) and thus is lowered by the threshold voltage Vthn or more than the gate low voltage VGL, which is a voltage (Vgn) of the gate electrode of the reset transistor in the turn-off state, the reset transistor is turned on, which may cause leakage current, i.e., off-leakage current.

If this off-leakage current occurs, the voltage of the Q node or Q2 node is not maintained but fluctuates abnormally, which may cause the stage to malfunction and reduce reliability of an output signal.

However, the reset circuit of this embodiment can be provided with an additional transistor that is connected to the reset transistor and performs function of preventing unintended off-leakage current of the reset transistor by allowing the voltage Vsn of the source electrode to be maintained equal to or higher than the gate low voltage VGL in the off state.

The reset circuit of this embodiment is described in more detail below.

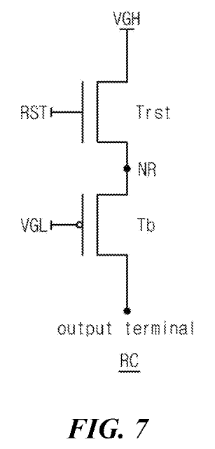

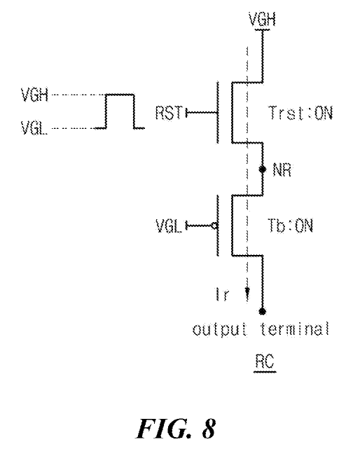

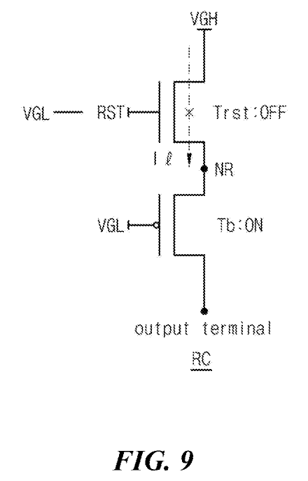

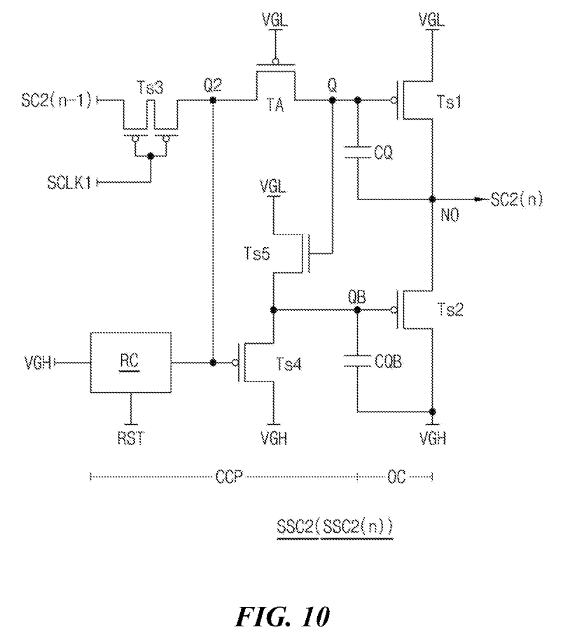

FIG. 7 is a view schematically illustrating a structure of a reset circuit according to a first embodiment of the present disclosure. FIGS. 8 and 9 are views schematically illustrating operation of a reset circuit according to a first embodiment of the present disclosure. FIG. 8 schematically illustrates a state in which the reset circuit is turned on and outputs a reset voltage, and FIG. 9 schematically illustrates a state in which the reset circuit is turned off and does not output a reset voltage. FIG. 10 is a view schematically illustrating an example of a structure of a scan driving circuit to which a reset circuit of FIG. 7 is applied.

In this embodiment, for convenience of explanation, as a gate driving circuit to which a reset circuit RC is applied, a second scan driving circuit that generates a second scan signal is taken as an example. Meanwhile, the reset circuit RC of this embodiment can be applied to at least one of a first scan driving circuit, a third scan driving circuit, a fourth scan driving circuit, a first emission driving circuit, and a second emission driving circuit.

In addition, in FIG. 10, a second scan stage SSC2(n) arranged in a n-th horizontal line among second scan stages SSC2 constituting the second scan driving circuit is illustrated as an example.

Referring to FIGS. 7 and 10 together with FIGS. 1 to 6, the reset circuit RC of this embodiment can include, for example, a reset transistor Trst and an auxiliary transistor Tb which is connected in series with the reset transistor Trst and functions to prevent an off-current leakage. As such, the reset transistor Trst and the auxiliary transistor Tb can be connected in series with a node NR therebetween.

The reset transistor Trst can include, for example, an oxide semiconductor having excellent off-current characteristics. The reset transistor Trst can be configured as an N-type transistor.

As such, the reset transistor Trst, which is an N-type transistor with an oxide semiconductor, can be formed with the same structure as, for example, the N-type transistors (e.g., T1 and T7) with an oxide semiconductor in the pixel P.

The reset transistor Trst can output the gate high voltage VGH as a reset voltage in response to a reset signal RST.

In this regard, the reset transistor Trst can have a gate electrode that receives the reset signal RST, a drain electrode as a second electrode that receives the gate high voltage VGH, and a source electrode as a first electrode that is connected to the auxiliary transistor Tb. The drain electrode of the reset transistor Trst to which the gate high voltage VGH is input can serve as an input terminal of the reset circuit RC.

The auxiliary transistor Tb can include, for example, polycrystalline silicon having excellent mobility characteristics, but not limited thereto. The auxiliary transistor Tb can be configured as a P-type transistor.

As such, the auxiliary transistor Tb, which is a P-type transistor with polycrystalline silicon, can be formed with the same structure as, for example, the P-type transistors (e.g., T2 to T6 and DT) with polycrystalline silicon in the pixel P.

During a reset period, the auxiliary transistor Tb can output the gate high voltage VGH, which is a reset voltage output through the reset transistor Trst in a turned-on state, in response to a continuously applied gate low voltage VGL.

During a reset off period between adjacent reset periods (i.e., during a period between a current reset period and a next reset period) (e.g., during the frame FR), the auxiliary transistor Tb can operate so that, in response to the continuously applied gate low voltage VGL, a voltage (Vsn) of the source electrode of the reset transistor Trst in a turned-off state is higher than the gate low voltage VGL. For example, the auxiliary transistor Tb can operate so that the node NR, which the reset transistor Trst is connected to, is applied with the voltage which is │Vthp│ or more (or at least │Vthp│) higher than the gate low voltage VGL, that is, which is equal to or higher than (VGL + │Vthp│) (where │Vthp│is an absolute value of a threshold voltage (Vthp) of the auxiliary transistor Tb).

In this regard, the auxiliary transistor Tb can have a gate electrode that receives the gate low voltage VGL, a source electrode as a first electrode that is connected to the source electrode of the reset transistor Trst (i.e., the node NR), and a drain electrode as a second electrode that functions as an output terminal of the reset circuit RC.

The operation of the reset circuit RC configured with the reset transistor Trst and the auxiliary transistor Tb as described above is described with further reference to FIGS. 8 and 9.

First, referring to FIG. 8, the reset operation that outputs the reset voltage during the reset period is described. During the reset period, the reset signal RST can have a high state, that is, the gate high voltage VGH.

Accordingly, the N-type reset transistor Trst can be turned on. At this time, a voltage of (VGH - Vthn) can be applied to the source electrode of the reset transistor Trst (where Vthn is a threshold voltage of the reset transistor Trst).

As such, as the reset transistor Trst is turned on during the reset period, the voltage Vsn of its source electrode (or the voltage of the node NR) can be set to Vsn = (VGH - Vthn).

Meanwhile, during the reset period, the P-type auxiliary transistor Tb can be applied with a voltage of a low state, i.e., the gate low voltage VGL and thus be turned on.

In this regard, a voltage (Vsp) of the source electrode of the auxiliary transistor Tb can actually have the voltage Vsn of the source electrode of the reset transistor Trst connected thereto, so the voltage Vsp of the source electrode of the auxiliary transistor Tb can become Vsp = (VGH - Vthn).

In this case, if the voltage Vsp of the source electrode of the auxiliary transistor Tb is higher than a sum of the gate low voltage VGL applied to its gate electrode and the absolute value │Vthp│ of the threshold voltage Vthp of the auxiliary transistor Tb, the auxiliary transistor Tb can be turned on.

In other words, if (VGH - Vthn) > (VGL + │Vthp│) is satisfied, the auxiliary transistor Tb can be turned on. That is, if (VGH - VGL) > (Vthn + │Vthp│), the auxiliary transistor Tb can be turned on.

In this regard, in a normal operation of a display apparatus, (VGH - VGL) is a large value of 5V or greater, and compared to this, (Vthn + │Vthp│) is considerably small.

Accordingly, in the reset period, the auxiliary transistor Tb can be turned on normally.

As such, in the reset period, the voltage Vsp (= (VGH - Vthn)) of the source electrode of the auxiliary transistor Tb can be set to be greater than the absolute value (│Vthp│) of its threshold voltage compared to the gate low voltage VGL input to its gate electrode, so the auxiliary transistor Tb can be turned on without a problem.

As such, since the auxiliary transistor Tb is turned on, a reset current Ir can flow from the input terminal to the output terminal of the reset circuit RC through the reset transistor Trst and the auxiliary transistor Tb of the reset circuit RC, so that a high-level reset voltage can be output to the output terminal of the reset circuit RC.

Next, referring to FIG. 9, the reset off operation in which the reset voltage is not output after the reset period is described. During the reset off period after the reset period, the reset signal RST can have a low state, that is, the gate low voltage VGL.

Accordingly, the N-type reset transistor Trst can be turned off.

Meanwhile, during the reset off period, the voltage of a low state, that is, the gate low voltage VGL can be applied to the P-type auxiliary transistor Tb to be turned on.

Accordingly, the voltage Vsp of the source electrode of the auxiliary transistor Tb can be (VGL + │Vthp│) or higher.

As such, when the reset transistor Trst is in the turn-off state, the auxiliary transistor Tb is in the turn-on state, so that the voltage Vsp of the source electrode of the auxiliary transistor Tb can be set to (VGL + │Vthp│) or higher.

As a result, during the reset off period, the voltage Vsn of the source electrode of the reset transistor Trst can actually have the voltage Vsp of the source electrode of the auxiliary transistor Tb connected thereto, so that the voltage Vsn of the source electrode of the reset transistor Trst can be set to (VGL + │Vthp│) or higher.

As such, during the reset off period, the voltage Vsn of the source electrode of the reset transistor Trst can be set to be the gate low voltage VGL or higher, so that the turn-off state of the reset transistor Trst can be stably maintained.

In this regard, as mentioned above, during the reset off period when the gate low voltage VGL is applied to the N-type reset transistor Trst, if the voltage Vsn of the source electrode of the reset transistor Trst becomes equal to or lower than (VGL - Vthn), the reset transistor Trst is unintentionally turned on, which may cause an off-leakage current Il to occur.

However, the reset circuit RC of this embodiment can include the P-type auxiliary transistor Tb connected between the source electrode of the reset transistor Trst and the output terminal of the reset circuit RC.

By means of the auxiliary transistor Tb, during the turn-off period of the reset transistor Trst, the voltage Vsn of the source electrode of the reset transistor Trst can be set to the voltage Vsp of the source electrode of the auxiliary transistor Tb, and the voltage Vsn of the source electrode of the reset transistor Trst can be (VGL + │Vthp│) or more.

As such, the source electrode of the reset transistor Trst can stably have a voltage higher than the gate low voltage VGL, so that the turn-off state of the reset transistor Trst can be stably secured.

Accordingly, the off-leakage current Il flowing through the reset transistor Trst can be prevented, so that the voltage of the output terminal of the reset circuit RC is not affected by the off-leakage current Il.

Due to this, a voltage of a Q node or Q2 node in a stage to which the reset circuit RC is connected can be prevented from abnormally fluctuating due to the off-leakage current Il, so that the stage’s malfunction due to the off-leakage current Il can be prevented and reliability of a signal output therefrom can be improved.

As an example of the gate driving circuit to which the reset circuit RC as above is applied, a configuration of a second scan driving circuit that generates a second scan signal SC2 is described with further reference to FIG. 10.

The second scan driving circuit can include a plurality of second scan stages SSC2 that respectively correspond to a plurality of second scan lines SCL2 arranged in the display region AA and output respective second scan signals SC2.

Regarding the configuration of the second scan stage SSC2, the n-th second scan stage SCC2(n) is taken as an example. The n-th second scan stage SCC2(n) can include an output portion OC, and a control portion CCP that controls output operation of the output portion OC.

In this regard, the output portion OC can include, for example, a pull-up transistor (or Q transistor) Ts1, a pull-down transistor (or QB transistor) Ts2, a Q capacitor CQ, and a QB capacitor CQB.

The control portion CCP can include, for example, a transfer transistor TA and a plurality of control transistors Ts3, Ts4 and Ts5. Here, the plurality of control transistors Ts3, Ts4, and Ts5 can include, for example, first, second, and third control transistors (or eighth, ninth, and tenth transistors) Ts3, Ts4, and Ts5.

Furthermore, the control portion CCP can include a reset circuit RC. Meanwhile, in this embodiment, a case in which the reset circuit RC is connected to a Q2 node in the second scan stage SSC2 is taken as an example.

Each of the plurality of transistors Ts1 to Ts5, and TA, constituting the second scan stage SSC2(n), other than the reset circuit RC can be a P-type transistor or an N-type transistor. In addition, each of the plurality of transistors Ts1 to Ts5, and TA constituting the second scan stage SSC2(n) can be a transistor using an oxide semiconductor or a transistor using polycrystalline silicon.

In this embodiment, a case in which, among the plurality of transistors Ts1 to Ts5, and TA constituting the second scan stage SSC2(n), the pull-up transistor Ts1, the pull-down transistor Ts2, the transfer transistor TA, and the first and second control transistors Ts3, Ts4 are configured as P-type transistors including polycrystalline silicon layers, and the third control transistor Ts5 is configured as an N-type transistor including an oxide semiconductor layer is taken as an example.

Here, the N-type transistor Ts5 with the oxide semiconductor can be formed, for example, with the same structure as the N-type transistors (e.g., T1 and T7) with the oxide semiconductor in the pixel P. The P-type transistors Ts1 to Ts4, and TA with the polycrystalline silicon can be formed, for example, with the same structure as the P-type transistors (e.g., T2 to T6, and DT) with the polycrystalline silicon in the pixel P.

The pull-up transistor Ts1 of the output portion OC can pull-up drive an output terminal NO of the second scan stage SSC2(n) in response to a signal of the Q node applied to its gate electrode. In addition, the pull-down transistor Ts2 can pull-down drive the output terminal NO in response to a signal of the QB node applied to its gate electrode.

The P-type pull-up transistor Ts1 can, for example, have a second electrode (or drain electrode) that receives a gate low voltage VGL, and a first electrode (or source electrode) that is connected to the output terminal NO of the second scan stage SSC2(n).

In addition, the P-type pull-down transistor Ts2 can have, for example, a second electrode (or drain electrode) connected to the output terminal NO, and a first electrode (or source electrode) supplied with a gate high voltage VGH.

Meanwhile, the transfer transistor TA of the control portion CCP can transfer charges of a Q2 node to the Q node in response to the gate low voltage VGL applied to its gate electrode. The P-type transfer transistor TA can have, for example, a gate electrode applied with the gate low voltage VGL, a first electrode (or source electrode) connected to the Q2 node, and a second electrode (or drain electrode) connected to the Q node.

The first control transistor Ts3 can provide a previous second scan signal SC2(n-1), which is an output signal of the previous second scan stage SSC2, to the Q2 node in response to its corresponding scan clock SCLK1. The P-type first control transistor Ts3 can have, for example, a gate electrode to which the scan clock SCLK1 is applied, a first electrode (or source electrode) to which the previous second scan signal SC2(n-1) is applied, and a second electrode (or drain electrode) to which the Q2 node is connected. Here, the scan clock SCLK1 input to the n-th second scan stage SSC2(n) can be referred to as a first scan clock SCLK1.

Here, the previous second scan signal SC2(n-1) applied to the first control transistor Ts3 can be used as a start signal (or carry signal). Meanwhile, when the second scan stage SSC2(n) is a scan stage of the first horizontal line, a start signal provided from the timing control portion 240 can be input to the first control transistor Ts3 to start its output operation.

In addition, the second control transistor Ts4 can transmit the gate high voltage VGH to the QB node in response to the voltage of the Q2 node. The P-type second control transistor Ts4 can have, for example, a gate electrode connected to the Q2 node, a second electrode (or a drain electrode) connected to the QB node, and a first electrode (or a source electrode) to which the gate high voltage VGH is applied.

In addition, the third control transistor Ts5 can be connected in series with the second control transistor Ts4 with the QB node interposed therebetween, and can transmit the gate low voltage VGL to the QB node in response to the voltage of the Q node. The N-type third control transistor Ts5 can, for example, have a gate electrode connected to the Q node, a second electrode (or a drain electrode) connected to the QB node, and a first electrode (or a source electrode) to which the gate low voltage VGL is applied.

Meanwhile, the Q capacitor CQ can be connected between the Q node and the output terminal NO, and the QB capacitor CQB can be connected between the QB node and a line transmitting the gate high voltage VGH. Here, a capacitance of the Q capacitor CQ and a capacitance of the QB capacitor CQB can each be set to be larger than a capacitance of the storage capacitor Cst in the pixel P.

The second scan stage SSC2(n) configured as above can shift the previous second scan signal SC2(n-1) according to the scan clock SCLK1 input thereto and output the corresponding second scan signal SC2(n) to the corresponding second scan line SCL2.

As such, the second scan stage SSC2(n) of the n-th horizontal line can receive the scan clock SCLK1 to perform a signal output operation.

Meanwhile, the second scan stages SSC2 located in n-1-th and n+1-th horizontal lines, which are preceding and following the n-th horizontal line, can receive their corresponding scan clocks which are different in phase from the scan clock SCLK1 input to the n-th second scan stage SSC2(n), for example, second scan clocks, and perform operation of outputting their corresponding second scan signals SC2.

The reset circuit RC can be connected to the Q2 node of the second scan stage SSC2 configured as above.

In this regard, as mentioned above, the reset circuit RC can be configured with the reset transistor Trst connected to an input terminal that receives the gate high voltage VGH which is the reset voltage, and the auxiliary transistor Tb that is connected in series to the reset transistor Trst and outputs the reset voltage.

Here, the auxiliary transistor Tb can be connected to the Q2 node of the second scan stage SSC2(n). More specifically, the drain electrode of the auxiliary transistor Tb can be connected to the Q2 node of the second scan stage SSC2(n).

As such, through the reset circuit RC connected to the Q2 node, the Q2 node can be reset, and as a result, the Q node, which is electrically short-circuited to the Q2 node through the transfer transistor TA, can be reset.

For example, as mentioned above, when the reset signal RST of a high state (i.e., gate high voltage VGH) is applied to the reset circuit RC during the reset period, both the reset transistor Trst and the auxiliary transistor Tb arranged in the reset circuit RC are turned on, so that the gate high voltage VGH, which is the reset voltage, can be transmitted to the Q2 node.

Accordingly, the reset voltage is transmitted from the Q2 node to the Q node, and the Q node can be reset to a high state.

In addition, when the Q2 node and the Q node are reset to a high state, the second control transistor Ts4 can be turned off, the third control transistor Ts5 can be turned on, and the gate low voltage VGL can be transmitted to the QB node through the third control transistor Ts5, so that the QB node can be reset to a low state.

During the reset off period after the reset period, as mentioned above, the reset signal RST is switched to a low state, i.e., the gate low voltage VGL, the reset transistor Trst can be turned off, and the auxiliary transistor Tb can have a turn-on state.

At this time, the voltage Vsn of the source electrode of the reset transistor Trst can be set to (VGL + │Vthp│) or more, so that the turn-off state of the reset transistor Trst can be stably maintained.

Accordingly, the off-leakage current Il flowing through the reset transistor Trst can be prevented.

Thus, the off-leakage current Il of the reset circuit RC can be prevented from flowing into the Q2 node connected to the output terminal of the reset circuit RC, and as a result, the off-leakage current Il can be prevented from flowing into the Q node.

In this regard, as mentioned above, when the reset circuit RC is configured only with the reset transistor Trst without the auxiliary transistor Tb, the Q2 node is electrically coupled with the scan clock SCLK1 input to the first control transistor Ts3 connected thereto, so that the voltage of the source electrode of the reset transistor Trst may become (VGL - Vthn) or lower. In this case, the off-leakage current Il may be generated through the reset transistor Trst and flow into the Q2 node and the Q node, so that the voltages of the Q2 node and the Q node may fluctuate abnormally. As a result, a leakage current may be generated through the Q capacitor CQ and flow into the Q node (and the Q2 node), so that the voltage of the Q node (and the voltage of the Q2 node) may fluctuate abnormally.

On the other hand, in this embodiment, by adding the auxiliary transistor Tb to the reset circuit RC, the source electrode of the reset transistor Trst can stably have the voltage higher than the gate low voltage VGL during the reset off period, so that the turn-off state of the reset transistor Trst can be stably secured.

Accordingly, the off-leakage current of the reset circuit RC can be prevented, so that the leakage current can be prevented from flowing into the Q2 node and Q node electrically connected to the output terminal of the reset circuit RC, and thus, it can be free from the influence of the leakage current.

Therefore, the voltages of the Q node and Q2 node of the second scan stage SSC2 can be prevented from abnormally fluctuating due to the leakage current, so that the malfunction of the second scan stage SSC2 due to the leakage current can be prevented, and the reliability of the signal output therefrom can be improved.

### Second Embodiment

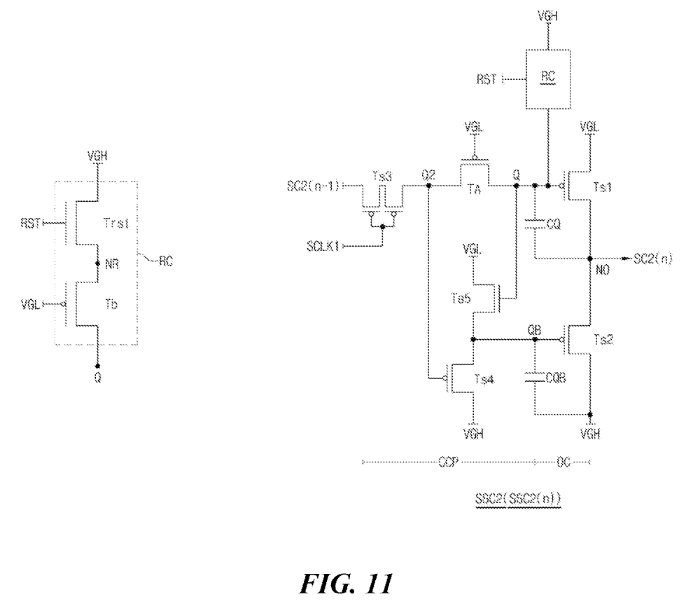

FIG. 11 is a view schematically illustrating an example of a structure of a scan driving circuit to which a reset circuit is applied according to a second embodiment of the present disclosure.

In the following description, specific descriptions of configurations identical to or similar to those of the first embodiment described above can be omitted.

The gate driving portion of this embodiment can be provided with a reset circuit RC in which a P-type auxiliary transistor Tb is connected to a reset transistor Trst formed of an N-type oxide semiconductor, thereby preventing an off-leakage current of the reset transistor Trst, similar to the first embodiment.

Meanwhile, unlike the first embodiment, the reset circuit RC of this embodiment can be connected to the Q node.

In this regard, with reference to FIG. 11, as an example of the gate driving circuit to which the reset circuit RC is applied, a configuration of a second scan driving circuit that generates a second scan signal SC2 is described.

The second scan stage SSC2 can be configured similarly to the n-th second scan stage SSC2 of the first embodiment, and a detailed description thereof can be omitted.

A reset circuit RC can be connected to the Q node of the second scan stage SSC2.

In this regard, the reset circuit RC can be configured with a reset transistor Trst connected to an input terminal that receives a gate high voltage VGH, which is a reset voltage, and an auxiliary transistor Tb that is connected in series to the reset transistor Trst and outputs the reset voltage.

Here, the auxiliary transistor Tb can be connected to the Q node of the second scan stage SSC2(n). More specifically, the drain electrode of the auxiliary transistor Tb can be connected to the Q node of the second scan stage SSC2(n).

As such, the Q node can be reset through the reset circuit RC connected to the Q node.

For example, similarly to the first embodiment described above, when the reset signal RST of a high state (i.e., a gate high voltage VGH) is applied to the reset circuit RC during the reset period, both of the reset transistor Trst and the auxiliary transistor Tb arranged in the reset circuit RC can be turned on, so that the gate high voltage VGH, which is a reset voltage, can be transmitted to the Q node.

Accordingly, the reset voltage can be transmitted to the Q node, and the Q node can be reset to a high state. At this time, the Q2 node, which is electrically short-circuited to the Q node through the transfer transistor TA, can also be reset to a high state.

When the Q node is reset to a high state, the second control transistor Ts4 can be turned off and the third control transistor Ts5 can be turned on, and the gate low voltage VGL can be transmitted to the QB node through the third control transistor Ts5, so that the QB node can be reset to a low state.

During the reset off period after the reset period, as mentioned above, the reset signal RST is switched to a low state, that is, the gate low voltage VGL, the reset transistor Trst can be turned off, and the auxiliary transistor Tb can have a turn-on state.

At this time, the voltage Vsn of the source electrode of the reset transistor Trst can be set to (VGL + │Vthp│) or more, so that the turn-off state of the reset transistor Trst can be stably maintained.

Accordingly, the off-leakage current flowing through the reset transistor Trst can be prevented.

As a result, the off-leakage current of the reset circuit RC can be prevented from flowing into the Q node connected to the output terminal of the reset circuit RC. In addition, the off-leakage current can be prevented from flowing into the Q2 node.

As such, in this embodiment, by adding the auxiliary transistor Tb to the reset circuit RC, the source electrode of the reset transistor Trst can stably have the voltage higher than the gate low voltage VGL during the reset off period, so that the turn-off state of the reset transistor Trst can be stably secured.

Accordingly, the off-leakage current of the reset circuit RC can be prevented, so that the leakage current can be prevented from flowing into the Q node (and Q2 node) connected to the output terminal of the reset circuit RC, and thus it can be prevented from being affected by the leakage current.

Due to this, the voltage of the Q node (and Q2 node) of the second scan stage SSC2 can be prevented from abnormally fluctuating due to the leakage current, so that malfunction of the second scan stage SSC2 due to leakage current can be prevented and the reliability of the signal output therefrom can be improved.

### Third Embodiment

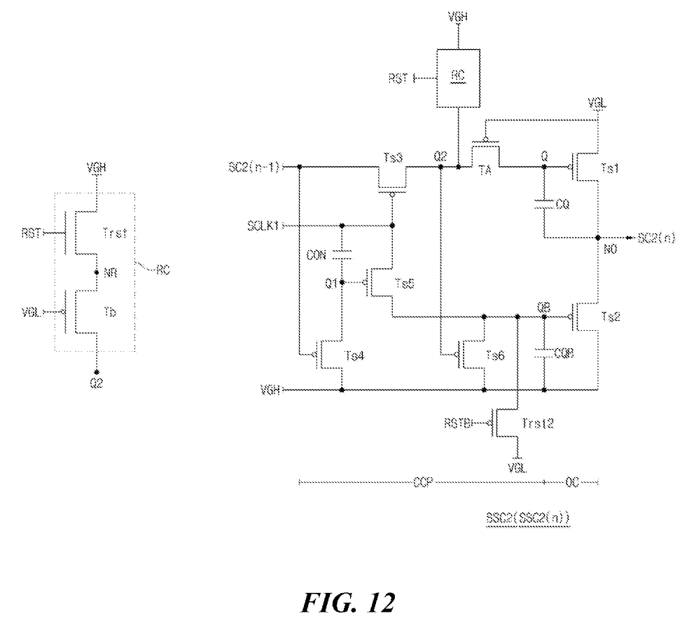

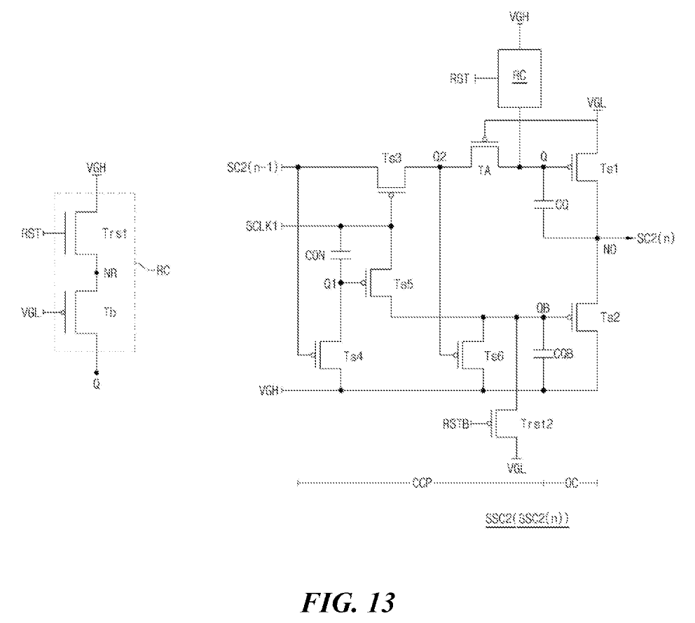

FIG. 12 is a view schematically illustrating a first example of a structure of a scan driving circuit to which a reset circuit is applied according to a third embodiment of the present disclosure, and FIG. 13 is a view schematically illustrating a second example of a structure of a scan driving circuit to which a reset circuit is applied according to a third embodiment of the present disclosure.

In the following description, specific descriptions of configurations identical to or similar to those of the first and second embodiments described above can be omitted.

The gate driving portion of this embodiment can be provided with a reset circuit RC in which a P-type auxiliary transistor Tb is connected to a reset transistor Trst formed of an N-type oxide semiconductor, thereby preventing an off-leakage current of the reset transistor Trst, similar to the first and second embodiments.

In addition, regarding a node to which the reset circuit RC of this embodiment is connected, in the first example of FIG. 12, the reset circuit RC can be connected to the Q2 node similarly to the first embodiment, and in the second example of FIG. 13, the reset circuit RC can be connected to the Q node similarly to the second embodiment.

Meanwhile, the gate driving circuit of this embodiment to which the reset circuit RC is applied can be configured with a structure different from the first and second embodiments.

In this regard, with reference to FIGS. 12 and 13, as an example of the gate driving circuit to which the reset circuit RC is applied, a configuration of a second scan driving circuit that generates a second scan signal SC2 is described.

The second scan driving circuit can include a plurality of second scan stages SSC2 that respectively correspond a plurality of second scan lines arranged in a display region and output respective second scan signals.

Regarding the configuration of the second scan stage SSC2, the n-th second scan stage SCC2(n) is taken as an example. The second scan stage SCC2(n) can include an output portion OC and a control portion CCP that controls the output operation of the output portion OC.

In this regard, the output section OC can include, for example, a pull-up transistor (or Q transistor) Ts1, a pull-down transistor (or QB transistor) Ts2, a Q capacitor CQ, and a QB capacitor CQB.

The control portion CCP can include, for example, a transfer transistor TA, a plurality of control transistors Ts3, Ts4, Ts5, and Ts6, and an on capacitor CON. Here, the plurality of control transistors Ts3, Ts4, Ts5, and Ts6 can include, for example, first, second, third, and fourth control transistors (or eighth, ninth, tenth, and eleventh transistors) Ts3, Ts4, Ts5, and Ts6.

Furthermore, the control portion CCP can include a reset circuit RC.

As mentioned above, the reset circuit RC can be connected to the Q2 node in the second scan stage SSC2 in the first example of this embodiment. The reset circuit RC can be connected to the Q node in the second scan stage SSC2 in the second example of this embodiment.

In addition, the control portion CCP can include a reset transistor Trst2 connected to the QB node and resetting the QB node.

Here, for convenience of explanation, the reset transistor Trst of the reset circuit RC electrically connected to the Q node and resetting it can be referred to as a first reset transistor Trst, and the reset transistor Trst2 connected to the QB node and resetting it can be referred to as a second reset transistor Trst2.

Each of the plurality of transistors Ts1 to Ts6, and TA, constituting the second scan stage SSC2(n), other than the reset circuit RC and the second reset transistor Trst2 can be a P-type transistor or an N-type transistor. In addition, each of the transistors Ts1 to Ts6, and TA can be a transistor using an oxide semiconductor or a transistor using polycrystalline silicon.

In this embodiment, a case in which the above transistors Ts1 to Ts6, and TA are configured as P-type transistors including polycrystalline silicon layers is taken as an example.

Meanwhile, in this embodiment, the second reset transistor Trst2 can be configured as a P-type transistor including a polycrystalline silicon layer.

The P-type transistors Ts1 to Ts6, TA, and Trst2 of polycrystalline silicon can be formed, for example, with the same structure as the P-type transistors (e.g., T2 to T6, DT of FIG. 2) of polycrystalline silicon in the pixel (P of FIG. 2).

The pull-up transistor Ts1 of the output portion OC can pull-up drive an output terminal NO of the second scan stage SSC2(n) in response to a signal of the Q node applied to its gate electrode. In addition, the pull-down transistor Ts2 can pull-down drive the output terminal NO in response to a signal of the QB node applied to its gate electrode.

The P-type pull-up transistor Ts1 can, for example, have a second electrode (or drain electrode) that receives a gate low voltage VGL, and a first electrode (or source electrode) that is connected to the output terminal NO of the second scan stage SSC2(n).

In addition, the P-type pull-down transistor Ts2 can, for example, have a second electrode (or drain electrode) that is connected to the output terminal NO, and a first electrode (or source electrode) that is provided with a gate high voltage VGH.

Meanwhile, the transfer transistor TA of the control portion CCP can transfer charges of the Q2 node to the Q node in response to the gate low voltage VGL applied to its gate electrode. The P-type transfer transistor TA can have, for example, a gate electrode applied with the gate low voltage VGL, a first electrode (or source electrode) connected to the Q2 node, and a second electrode (or drain electrode) connected to the Q node.

The first control transistor Ts3 can provide a previous second scan signal SC2(n-1), which is an output signal of the previous second scan stage SSC2, to the Q2 node in response to its corresponding scan clock SCLK1. The P-type first control transistor Ts3 can have, for example, a gate electrode to which the scan clock SCLK1 is applied, a first electrode (or source electrode) to which the previous second scan signal SC2(n-1) is applied, and a second electrode (or drain electrode) to which the Q2 node is connected. Here, the scan clock SCLK1 input to the n-th second scan stage SSC2(n) can be referred to as a first scan clock SCLK1.

Here, the previous second scan signal SC2(n-1) applied to the first control transistor Ts3 can be used as a start signal (or carry signal). Meanwhile, when the second scan stage SSC2(n) is a scan stage of the first horizontal line, a start signal provided from a timing control portion can be input to the first control transistor Ts3 to start its output operation.

In addition, the second control transistor Ts4 can transmit the gate high voltage VGH to a Q1 node in response to the previous second scan signal SC2(n-1). The second control transistor Ts4 can have, for example, a gate electrode that receives the previous second scan signal SC2(n-1), a first electrode (or source electrode) that receives the gate high voltage VGH, and a second electrode (or drain electrode) that is connected to the Q1 node.

In addition, the third control transistor Ts5 can provide the scan clock SCLK1 input thereto to the QB node in response to a voltage of the Q1 node. The third control transistor Ts5 can have, for example, a gate electrode that is connected to the Q1 node, a first electrode (or source electrode) that receives the scan clock SCLK1, and a second electrode (or drain electrode) that is connected to the QB node.

The fourth control transistor Ts6 can transmit the gate high voltage VGH to the QB node in response to a voltage of the Q2 node. The fourth control transistor Ts6 can have, for example, a gate electrode connected to the Q2 node, a second electrode (or a drain electrode) connected to the QB node, and a first electrode (or a source electrode) to which the gate high voltage VGH is applied.

Meanwhile, the Q capacitor CQ can be connected between the Q node and the output terminal NO, and the QB capacitor CQB can be connected between the QB node and a line transmitting the gate high voltage VGH. The on capacitor CON can be connected between an input terminal of a scan clock SCLK1 and the Q1 node. Here, a capacitances of the Q capacitor CQ and a capacitance of the QB capacitor CQB can each be set to be larger than a capacitance of the on capacitor CON. In addition, the capacitance of the on capacitor CON can be set to be larger than a capacitance of a storage capacitor (Cst of FIG. 2) in a pixel (P of FIG. 2).

The second scan stage SSC2(n) configured as above can shift the previous second scan signal SC2(n-1) according to the scan clock SCLK1 input thereto and output the corresponding second scan signal SC2(n) to the corresponding second scan line.

As such, the second scan stage SSC2(n) of the n-th horizontal line can receive the scan clock SCLK1 to perform a signal output operation.

Regarding the second scan stage SSC2 configured as above, in the first example, the reset circuit RC can be connected to the Q2 node, and in the second example, the reset circuit RC can be connected to the Q node.

In this regard, the reset circuit RC can be configured with the first reset transistor Trst connected to an input terminal that receives the gate high voltage VGH, which is a reset voltage, and the auxiliary transistor Tb that is connected in series to the first reset transistor Trst and outputs the reset voltage.

Here, the auxiliary transistor Tb can be connected to the Q2 node in the first example, and can be connected to the Q node in the second example.

Through the reset circuit RC connected in this manner, the Q node and the Q2 node can be reset.

For example, as described in the first and second embodiments, when the reset signal RST in a high state (i.e., gate high voltage VGH) is applied to the reset circuit RC during the reset period, both the first reset transistor Trst and the auxiliary transistor Tb arranged in the reset circuit RC can be turned on. Accordingly, the gate high voltage VGH, which is the reset voltage, can be transmitted to the Q2 node in the first example, and to the Q node in the second example.

Accordingly, the Q2 node and the Q node can be reset to a high state.

During the reset off period after the reset period, as described in the first and second embodiments, the reset signal RST can be switched to a low state, i.e., the gate low voltage VGL, the first reset transistor Trst can be turned off, and the auxiliary transistor Tb can have a turn-on state.

At this time, the voltage Vsn of the source electrode of the first reset transistor Trst can be set to (VGL + │Vthp│) or more, so that the turn-off state of the first reset transistor Trst can be stably maintained.

Accordingly, the off-leakage current flowing through the first reset transistor Trst can be prevented.

Accordingly, the off-leakage current of the reset circuit RC can be prevented, so that the leakage current can be prevented from flowing into the Q2 node and Q node connected to the output terminal of the reset circuit RC, so that it can be free from the influence of the leakage current.

Therefore, the voltages of the Q2 node and Q node of the second scan stage SSC2 can be prevented from abnormally fluctuating due to the leakage current, so that the malfunction of the second scan stage SSC2 due to the leakage current can be prevented, and the reliability of the signal output therefrom can be improved.

Meanwhile, in this embodiment, as mentioned above, the second reset transistor Trst2 that resets the QB node can be additionally provided in the second scan stage SSC2.

The second reset transistor Trst2 can transmit the gate low voltage VGL to the QB node in response to a reset signal RSTB input thereto during a reset period, so that the QB node can be reset to a low state. Here, for convenience of explanation, the reset signal RST input to the first reset transistor Trst can be referred to as a first reset signal RST, and the reset signal RSTB input to the second reset transistor Trst2 can be referred to as a second reset signal RSTB.

At this time, the second reset signal RSTB can be a signal having an opposite phase to the first reset signal RST. In this case, during the reset period, the first reset signal RST can be in a high state and the second reset signal RSTB can be in a low state, and during the reset off period, the first reset signal RST can be in a low state and the second reset signal RSTB can be in a high state.

The second reset transistor Trst2 can have, for example, a gate electrode that receives the second reset signal RSTB, a second electrode (or drain electrode) that receives the gate low voltage VGL, and a first electrode (or source electrode) that is connected to the QB node.

Accordingly, during the reset period, when the second reset signal RSTB in a low state (i.e., gate low voltage VGL) is applied to the second reset transistor Trst2, the second reset transistor Trst2 can be turned on, so that the gate low voltage VGL, which is a reset voltage, can be transmitted to the QB node.

In addition, during the reset off period after the reset period, the second reset signal RSTB can be switched to a high state, i.e., the gate high voltage VGH, and the second reset transistor Trst2 can be turned off.

As such, in this embodiment, the second reset transistor Trst2 to reset the QB node can be additionally provided.

In this regard, in the circuit configuration of the second scan stage SSC2 of this embodiment, when the Q node is reset to a high state through the reset circuit RC, a reset of the QB node due to the reset of the Q node is not performed.

However, the second scan stage SSC2 of this embodiment can be separately provided with the second reset transistor Trst2 connected to the QB node, so that the QB node can be stably reset to a low state through the second reset transistor Trst2.

### Fourth embodiment

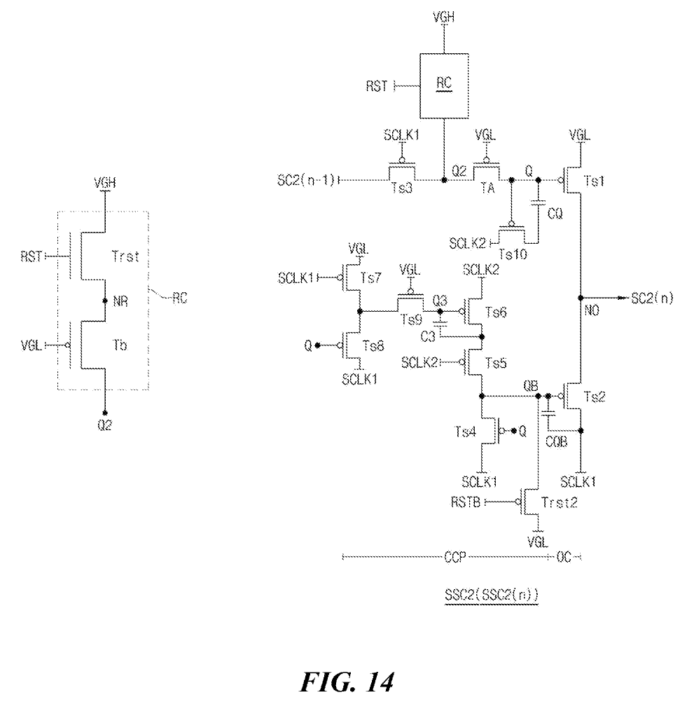

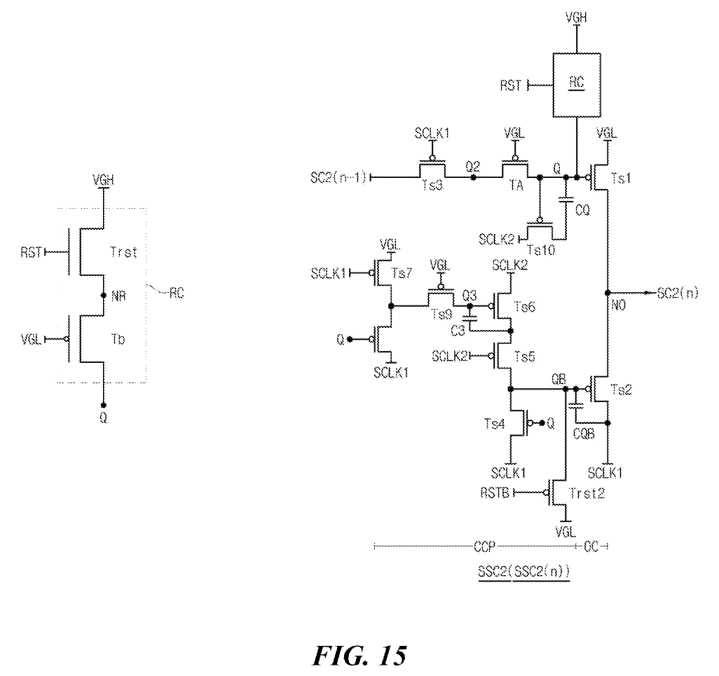

FIG. 14 is a view schematically illustrating a first example of a structure of a scan driving circuit to which a reset circuit is applied according to a fourth embodiment of the present disclosure, and FIG. 15 is a view schematically illustrating a second example of a structure of a scan driving circuit to which a reset circuit is applied according to a fourth embodiment of the present disclosure.

In the following description, specific descriptions of configurations identical to or similar to those of the first to third embodiments described above can be omitted.

The gate driving portion of this embodiment can be provided with a reset circuit RC in which a P-type auxiliary transistor Tb is connected to a reset transistor Trst formed of an N-type oxide semiconductor, thereby preventing an off-leakage current of the reset transistor Trst, similar to the first to third embodiments.

In addition, regarding a node to which the reset circuit RC of this embodiment is connected, in the first example of FIG. 14, the reset circuit RC can be connected to the Q2 node similarly to the first embodiment and the first example of the third embodiment, and in the second example of FIG. 15, the reset circuit RC can be connected to the Q node similarly to the second embodiment and the second example of the third embodiment.

Meanwhile, the gate driving circuit of this embodiment to which the reset circuit RC is applied can be configured with a structure different from the first to third embodiments.

In this regard, with reference to FIGS. 14 and 15, as an example of the gate driving circuit to which the reset circuit RC is applied, a configuration of a second scan driving circuit that generates a second scan signal SC2 is described.

The second scan driving circuit can include a plurality of second scan stages SSC2 that respectively correspond a plurality of second scan lines arranged in a display region and output respective second scan signals.

Regarding the configuration of the second scan stage SSC2, the n-th second scan stage SCC2(n) is taken as an example. The second scan stage SCC2(n) can include an output portion OC and a control portion CCP that controls the output operation of the output portion OC.

In this regard, the output portion OC can include, for example, a pull-up transistor (or Q transistor) Ts1, a pull-down transistor (or QB transistor) Ts2, a Q capacitor CQ, and a QB capacitor CQB.

The control portion CCP can include, for example, a transfer transistor TA, a plurality of control transistors Ts3 to Ts10, and a Q3 capacitor C3. Here, the plurality of control transistors Ts3 to Ts10 can include, for example, first to eighth control transistors (or eighth to fifteenth transistors) Ts3 to Ts10.

Furthermore, the control portion CCP can include a reset circuit RC.

As mentioned above, the reset circuit RC can be connected to the Q2 node in the second scan stage SSC2 in the first example of this embodiment. The reset circuit RC can be connected to the Q node in the second scan stage SSC2 in the second example of this embodiment.

In addition, the control portion CCP can include a reset transistor Trst2 connected to the QB node and resetting the QB node.

Here, for convenience of explanation, the reset transistor Trst of the reset circuit RC electrically connected to the Q node and resetting it can be referred to as a first reset transistor Trst, and the reset transistor Trst2 connected to the QB node and resetting it can be referred to as a second reset transistor Trst2.

Each of the plurality of transistors Ts1 to Ts10, and TA, constituting the second scan stage SSC2(n), other than the reset circuit RC and the second reset transistor Trst2 can be a P-type transistor or an N-type transistor. In addition, each of the transistors Ts1 to Ts10, and TA can be a transistor using an oxide semiconductor or a transistor using polycrystalline silicon.

In this embodiment, a case in which the above transistors Ts1 to Ts10, and TA are configured as P-type transistors including polycrystalline silicon layers is taken as an example.

Meanwhile, in this embodiment, the second reset transistor Trst2 can be configured as a P-type transistor including a polycrystalline silicon layer.

The P-type transistors Ts1 to Ts10, TA, and Trst2 of the polycrystalline silicon can be formed, for example, with the same structure as the P-type transistors (e.g., T2 to T6, and DT of FIG. 2) of polycrystalline silicon in the pixel (P of FIG. 2).

The pull-up transistor Ts1 of the output portion OC can pull-up drive an output terminal NO of the second scan stage SSC2(n) in response to a signal of the Q node applied to its gate electrode. In addition, the pull-down transistor Ts2 can pull-down drive the output terminal NO in response to a signal of the QB node applied to its gate electrode.

Meanwhile, the transfer transistor TA of the control portion CCP can transfer charges of the Q2 node to the Q node in response to the gate low voltage VGL applied to its gate electrode.

The first control transistor Ts3 can provide a previous second scan signal SC2(n-1), which is an output signal of the previous second scan stage SSC2, to the Q2 node in response to a first scan clock SCLK1 which is a scan clock corresponding to the first control transistor Ts3. The P-type first control transistor Ts3 can have, for example, a gate electrode to which the first scan clock SCLK1 is applied, a first electrode (or a source electrode) to which the previous second scan signal SC2(n-1) is applied, and a second electrode (or a drain electrode) to which the Q2 node is connected.

Here, the previous second scan signal SC2(n-1) applied to the first control transistor Ts3 can be used as a start signal (or a carry signal). Meanwhile, when the second scan stage SSC2(n) is a scan stage of the first horizontal line, a start signal provided from a timing control portion can be input to the first control transistor Ts3 to start its output operation.

In addition, the second control transistor Ts4 can have, for example, a gate electrode that is connected to the Q node, a first electrode (or source electrode) that is applied with its corresponding first scan clock SCLK1, and a second electrode (or drain electrode) that is connected to the QB node.

In addition, the third control transistor Ts5 can have, for example, a gate electrode that receives its corresponding second scan clock SCLK2, a first electrode (or source electrode) that is connected to the fourth control transistor Ts6, and a second electrode (or drain electrode) that is connected to the QB node.

In addition, the fourth control transistor Ts6 can have, for example, a gate electrode that is connected to the Q3 node, a first electrode (or source electrode) that receives its corresponding second scan clock SCLK2, and a second electrode (or drain electrode) that is connected to the third control transistor Ts5.

In addition, the fifth control transistor Ts7 can have, for example, a gate electrode that receives its corresponding first scan clock SCLK1, a second electrode (or drain electrode) that is applied with the gate low voltage VGL, and a first electrode (or source electrode) that is connected to the sixth control transistor Ts8.

In addition, the sixth control transistor Ts8 can have, for example, a gate electrode that is connected to the Q node, a first electrode (or source electrode) that receives its corresponding first scan clock SCLK1, and a second electrode (or drain electrode) that is connected to the fifth control transistor Ts7.

In addition, the seventh control transistor Ts9 can have, for example, a gate electrode that is applied with the gate low voltage VGL, a first electrode (or a source electrode) that is connected to a node between the fifth and sixth control transistors Ts7 and Ts8, and a second electrode (or a drain electrode) that is connected to the Q3 node.

In addition, the eighth control transistor Ts10 can have, for example, a gate electrode that is connected to the Q node, a first electrode (or a source electrode) that receives its corresponding second scan clock SCLK2, and a second electrode (or a drain electrode) connected to the Q capacitor CQ.

Meanwhile, the Q capacitor CQ can be connected between the Q node and the eighth control transistor Ts10, and the QB capacitor CQB can be connected between the QB node and the source electrode of the pull-down transistor Ts2. The Q3 capacitor C3 can be connected between the Q3 node and a node between the third and fourth control transistors Ts5 and Ts6. Here, a capacitance of the Q capacitor CQ and a capacitance of the QB capacitor CQB can each be set to be larger than a capacitance of the Q3 capacitor C3. In addition, the capacitance of the Q3 capacitor C3 can be set to be larger than a capacitance of a storage capacitor (Cst of FIG. 2) in the pixel (P of FIG. 2).

The second scan stage SSC2(n) configured as above can shift the previous second scan signal SC2(n-1) according to the scan clocks SCLK1 and SCLK2 input thereto and output the corresponding second scan signal SC2(n) to the corresponding second scan line.

As such, the second scan stage SSC2(n) of the n-th horizontal line can receive the scan clocks SCLK1 and SLCK2 to perform a signal output operation.

Meanwhile, positions of the first and second scan clocks SCLK1 and SCLK2 input to the second scan stages SSC2 located in the n-1-th and n+1-th horizontal lines, which are preceding and following the n-th horizontal line, can be opposite to positions of the first and second scan clocks SCLK1 and SCLK2 input to the second scan stage SSC2(n) in the n-th horizontal line. For example, the second scan clock SCLK2 can be input to the first control transistor Ts3 of each of the n-1-th and n+1-th second scan stages SSC2, and the first scan clock SCLK1 can be input to the third control transistor Ts5 of each of the n-1-th and n+1-th second scan stages SSC2.

Regarding the second scan stage SSC2 configured as above, in the first example, the reset circuit RC can be connected to the Q2 node, and in the second example, the reset circuit RC can be connected to the Q node.

In this regard, the reset circuit RC can be configured with the first reset transistor Trst connected to an input terminal that receives the gate high voltage VGH, which is a reset voltage, and the auxiliary transistor Tb that is connected in series to the first reset transistor Trst and outputs the reset voltage.

Here, the auxiliary transistor Tb can be connected to the Q2 node in the first example, and can be connected to the Q node in the second example.

Through the reset circuit RC connected in this way, the Q node and the Q2 node can be reset.

For example, as described in the first to third embodiments, when the reset signal RST in a high state (i.e., gate high voltage VGH) is applied to the reset circuit RC during the reset period, both the first reset transistor Trst and the auxiliary transistor Tb arranged in the reset circuit RC can be turned on. Accordingly, the gate high voltage VGH, which is the reset voltage, can be transmitted to the Q2 node in the first example, and to the Q node in the second example.

Accordingly, the Q2 node and the Q node can be reset to a high state.

During the reset off period after the reset period, as described in the first to third embodiments, the reset signal RST can be switched to a low state, i.e., the gate low voltage VGL, the first reset transistor Trst can be turned off, and the auxiliary transistor Tb can have a turn-on state.

At this time, since the voltage Vsn of the source electrode of the first reset transistor Trst can be set to (VGL + │Vthp│) or more, the turn-off state of the first reset transistor Trst can be stably maintained.

Accordingly, the off-leakage current flowing through the first reset transistor Trst can be prevented.

Accordingly, the off-leakage current of the reset circuit RC can be prevented, so that the leakage current can be prevented from flowing into the Q2 node and Q node connected to the output terminal of the reset circuit RC, and thus, it can be free from the influence of the leakage current.

Therefore, the voltages of the Q2 node and Q node of the second scan stage SSC2 can be prevented from abnormally fluctuating due to the leakage current, so that the malfunction of the second scan stage SSC2 due to the leakage current can be prevented, and the reliability of the signal output from it can be improved.

Meanwhile, in this embodiment, as mentioned above, the second reset transistor Trst2 that resets the QB node can be additionally provided in the second scan stage SSC2.

The second reset transistor Trst2 can transmit the gate low voltage VGL to the QB node in response to a reset signal RSTB input thereto during a reset period, so that the QB node can be reset to a low state. Here, for convenience of explanation, the reset signal RST input to the first reset transistor Trst can be referred to as a first reset signal RST, and the reset signal RSTB input to the second reset transistor Trst2 can be referred to as a second reset signal RSTB.

At this time, the second reset signal RSTB can be a signal having an opposite phase to the first reset signal RST. In this case, during the reset period, the first reset signal RST can be in a high state and the second reset signal RSTB can be in a low state, and during the reset off period, the first reset signal RST can be in a low state and the second reset signal RSTB can be in a high state.

The second reset transistor Trst2 can have, for example, a gate electrode that receives the second reset signal RSTB, a second electrode (or drain electrode) that receives the gate low voltage VGL, and a first electrode (or source electrode) that is connected to the QB node.

Accordingly, during the reset period, when the second reset signal RSTB in a low state (i.e., gate low voltage VGL) is applied to the second reset transistor Trst2, the second reset transistor Trst2 can be turned on, so that the gate low voltage VGL, which is the reset voltage, can be transmitted to the QB node.

In addition, during the reset off period after the reset period, the second reset signal RSTB can be switched to a high state, i.e., the gate high voltage VGH, and the second reset transistor Trst2 can be turned off.

As such, in this embodiment, the second reset transistor Trst2 to reset the QB node can be additionally provided.

In this regard, in the circuit configuration of the second scan stage SSC2 of this embodiment, similarly to the third embodiment, when the Q node is reset to a high state through the reset circuit RC, a reset of the QB node due to the reset of the Q node is not performed.

However, the second scan stage SSC2 of this embodiment can be separately provided with the second reset transistor Trst2 connected to the QB node, so that the QB node can be stably reset to a low state through the second reset transistor Trst2.

### Fifth embodiment

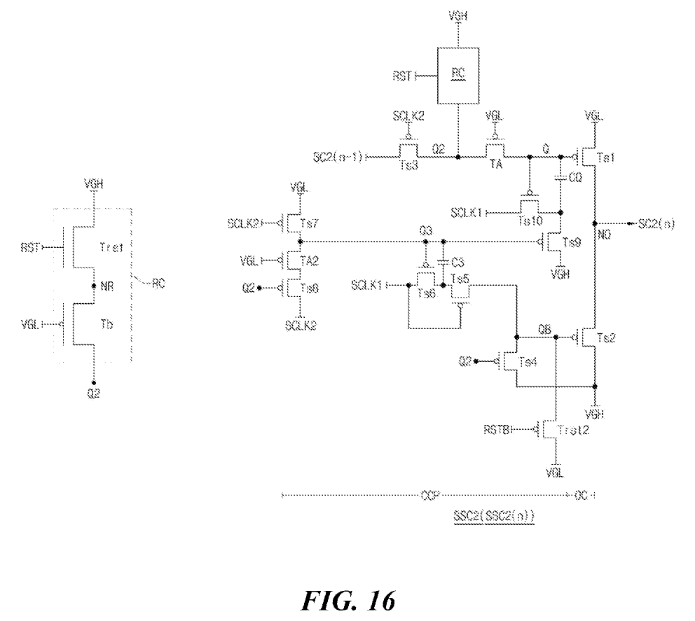

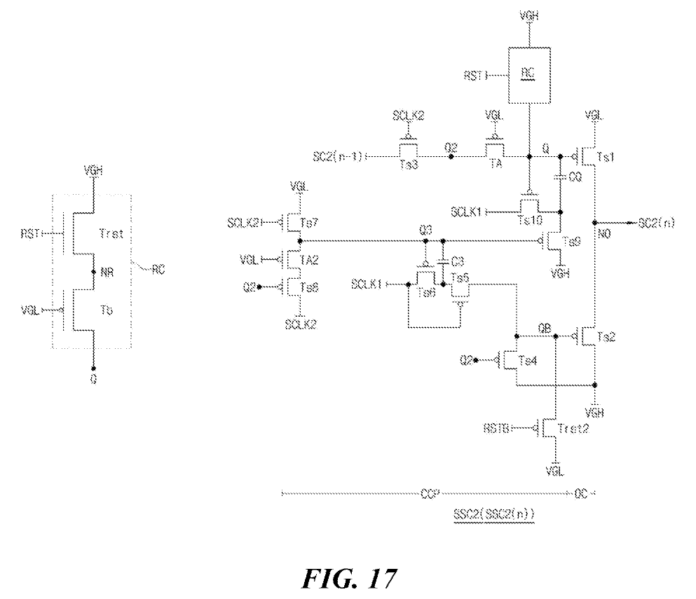

FIG. 16 is a view schematically illustrating a first example of a structure of a scan driving circuit to which a reset circuit is applied according to a fifth embodiment of the present disclosure, and FIG. 17 is a view schematically illustrating a second example of a structure of a scan driving circuit to which a reset circuit is applied according to a fifth embodiment of the present disclosure.

In the following description, specific descriptions of configurations identical to or similar to those of the first to fourth embodiments described above can be omitted.

The gate driving portion of this embodiment can be provided with a reset circuit RC in which a P-type auxiliary transistor Tb is connected to a reset transistor Trst formed of an N-type oxide semiconductor, thereby preventing an off-leakage current of the reset transistor Trst, similar to the first to fourth embodiments.

In addition, regarding a node to which the reset circuit RC of this embodiment is connected, in the first example of FIG. 16, the reset circuit RC can be connected to the Q2 node similarly to the first embodiment, the first example of the third embodiment, and the first example of the fourth embodiment, and in the second example of FIG. 17, the reset circuit RC can be connected to the Q node similarly to the second embodiment, the second example of the third embodiment, and the second example of the fourth embodiment.

Meanwhile, the gate driving circuit of this embodiment to which the reset circuit RC is applied can be configured with a structure different from the first to fourth embodiments.

In this regard, with reference to FIGS. 16 and 17, as an example of the gate driving circuit to which the reset circuit RC is applied, a configuration of a second scan driving circuit that generates a second scan signal SC2 is described.

The second scan driving circuit can include a plurality of second scan stages SSC2 that respectively correspond a plurality of second scan lines arranged in a display region and output respective second scan signals.

Regarding the configuration of the second scan stage SSC2, the n-th second scan stage SCC2(n) is taken as an example. The second scan stage SCC2(n) can include an output portion OC and a control portion CCP that controls the output operation of the output portion OC.

In this regard, the output portion OC can include, for example, a pull-up transistor (or Q transistor) Ts1, a pull-down transistor (or QB transistor) Ts2, and a Q capacitor CQ.

The control portion CCP can include, for example, transfer transistors TA and TA2, a plurality of control transistors Ts3 to Ts10, and a Q3 capacitor C3. Here, the plurality of control transistors Ts3 to Ts10 can include, for example, first to eighth control transistors (or eighth to fifteenth transistors) Ts3 to Ts10. For convenience of explanation, the transfer transistor TA can be referred to as a first transfer transistor TA, and the transfer transistor TA2 can be referred to as a second transfer transistor TA2.

Furthermore, the control portion CCP can include a reset circuit RC.

As mentioned above, the reset circuit RC can be connected to the Q2 node in the second scan stage SSC2 in the first example of this embodiment. The reset circuit RC can be connected to the Q node in the second scan stage SSC2 in the second example of this embodiment.

In addition, the control portion CCP can include a reset transistor Trst2 connected to the QB node and resetting the QB node.

Here, for convenience of explanation, the reset transistor Trst of the reset circuit RC connected to the Q node and resetting it can be referred to as a first reset transistor Trst, and the reset transistor Trst2 connected to the QB node and resetting it can be referred to as a second reset transistor Trst2.

Each of the plurality of transistors Ts1 to Ts10, TA, and TA2, constituting the second scan stage SSC2(n), other than the reset circuit RC and the second reset transistor Trst2 can be a P-type transistor or an N-type transistor. In addition, each of the transistors Ts1 to Ts10, TA, and TA2 can be a transistor using an oxide semiconductor or a transistor using polycrystalline silicon.

In this embodiment, a case where the above transistors Ts1 to Ts10, TA, and TA2 are configured as P-type transistors including polycrystalline silicon layers is taken as an example.

Meanwhile, in this embodiment, the second reset transistor Trst2 can be configured as a P-type transistor including a polycrystalline silicon layer.

The P-type transistors Ts1 to Ts10, TA, TA2, and Trst2 of the polycrystalline silicon can be formed, for example, with the same structure as the P-type transistors (e.g., T2 to T6, and DT of FIG. 2) of the polycrystalline silicon in the pixel (P of FIG. 2).

The pull-up transistor Ts1 of the output portion OC can pull-up drive an output terminal NO of the second scan stage SSC2(n) in response to a signal of the Q node applied to its gate electrode. In addition, the pull-down transistor Ts2 can pull-down drive the output terminal NO in response to a signal of the QB node applied to its gate electrode.

Meanwhile, the first transfer transistor TA of the control portion CCP can transfer charges of the Q2 node to the Q node in response to the gate low voltage VGL applied to its gate electrode.

The first control transistor Ts3 can provide a previous second scan signal SC2(n-1), which is an output signal of the previous second scan stage SSC2, to the Q2 node in response to its corresponding second scan clock SCLK2. The P-type first control transistor Ts3 can have, for example, a gate electrode that receives the second scan clock SCLK2, a first electrode (or source electrode) that receives the previous second scan signal SC2(n-1), and a second electrode (or drain electrode) that is connected to the Q2 node.

Here, the previous second scan signal SC2(n-1) applied to the first control transistor Ts3 can be used as a start signal (or carry signal). Meanwhile, when the second scan stage SSC2(n) is a scan stage of the first horizontal line, a start signal provided from a timing control portion can be input to the first control transistor Ts3 to start its output operation.

In addition, the second control transistor Ts4 can have, for example, a gate electrode that is connected to the Q2 node, a first electrode (or source electrode) that is applied with the gate high voltage VGH, and a second electrode (or drain electrode) connected to the QB node.

In addition, the third control transistor Ts5 can have, for example, a gate electrode applied with its corresponding first scan clock SCLK1, a first electrode (or source electrode) connected to the fourth control transistor Ts6, and a second electrode (or drain electrode) connected to the QB node.

In addition, the fourth control transistor Ts6 can have, for example, a gate electrode connected to the Q3 node, a first electrode (or source electrode) applied with its corresponding first scan clock SCLK1, and a second electrode (or drain electrode) connected to the third control transistor Ts5.

In addition, the fifth control transistor Ts7 can have, for example, a gate electrode applied with its corresponding second scan clock SCLK2, a second electrode (or drain electrode) applied with the gate low voltage VGL, and a first electrode (or source electrode) connected to the Q3 node.

In addition, the sixth control transistor Ts8 can have, for example, a gate electrode connected to the Q2 node, a first electrode (or source electrode) applied with its corresponding second scan clock SCLK2, and a second electrode (or drain electrode) connected to the second transfer transistor TA2.

In addition, the second transfer transistor TA2 can have, for example, a gate electrode applied with the gate low voltage VGL, a first electrode (or source electrode) connected to the sixth control transistor Ts8, and a second electrode (or drain electrode) connected to the Q3 node.

In addition, the seventh control transistor Ts9 can have, for example, a gate electrode connected to the Q3 node, a first electrode (or source electrode) applied with the gate high voltage VGH, and a second electrode (or drain electrode) connected to the Q capacitor CQ.

In addition, the eighth control transistor Ts10 can have, for example, a gate electrode connected to the Q node, a first electrode (or source electrode) receiving its corresponding first scan clock SCLK1, and a second electrode (or drain electrode) connected to the Q capacitor CQ.

Meanwhile, the Q capacitor CQ can be connected between the Q node and a node between the seventh and eighth control transistors Ts9 and Ts10. The Q3 capacitor C3 can be connected between the Q3 node and a node between the third and fourth control transistors Ts5 and Ts6. Here, a capacitance of the Q capacitor CQ can be set to be larger than a capacitance of the Q3 capacitor C3. In addition, the capacitance of the Q3 capacitor C3 can be set to be larger than a capacitance of a storage capacitor (Cst of FIG. 2) in the pixel (P of FIG. 2).

The second scan stage SSC2(n) configured as above can shift the previous second scan signal SC2(n-1) according to the scan clocks SCLK1 and SCLK2 input thereto and output the corresponding second scan signal SC2(n) to the corresponding second scan line.

As such, the second scan stage SSC2(n) of the n-th horizontal line can receive the scan clocks SCLK1 and SLCK2 to perform a signal output operation.

Meanwhile, positions of the first and second scan clocks SCLK1 and SCLK2 input to the second scan stage SSC2 located in the n-1-th and n+1-th horizontal lines, which are preceding and following the n-th horizontal line, can be opposite to positions of the first and second scan clocks SCLK1 and SCLK2 input to the second scan stage SSC2(n) in the n-th horizontal line. For example, the first scan clock SCLK1 can be input to the first control transistor Ts3 of each of the n-1-th and n+1-th second scan stages SSC2, and the second scan clock SCLK2 can be input to the third control transistor Ts5 of each of the n-1-th and n+1-th second scan stages SSC2.

Regarding the second scan stage SSC2 configured as above, in the first example, the reset circuit RC can be connected to the Q2 node, and in the second example, the reset circuit RC can be connected to the Q node.

In this regard, the reset circuit RC can be configured with the first reset transistor Trst connected to an input terminal that receives the gate high voltage VGH, which is a reset voltage, and the auxiliary transistor Tb that is connected in series to the first reset transistor Trst and outputs a reset voltage.

Here, the auxiliary transistor Tb can be connected to the Q2 node in the first example, and can be connected to the Q node in the second example.

Through the reset circuit RC connected in this way, the Q node and the Q2 node can be reset.

For example, as described in the first to fourth embodiments, when the reset signal RST in a high state (i.e., gate high voltage VGH) is applied to the reset circuit RC during the reset period, both the first reset transistor Trst and the auxiliary transistor Tb arranged in the reset circuit RC can be turned on. Accordingly, the gate high voltage VGH, which is the reset voltage, can be transferred to the Q2 node in the first example, and to the Q node in the second example.

Accordingly, the Q2 node and the Q node can be reset to a high state.

During the reset off period after the reset period, as described in the first to fourth embodiments, the reset signal RST can be switched to a low state, i.e., the gate low voltage VGL, the first reset transistor Trst can be turned off, and the auxiliary transistor Tb can have a turn-on state.

At this time, the voltage Vsn of the source electrode of the first reset transistor Trst can be set to (VGL + │Vthp│) or more, so that the turn-off state of the first reset transistor Trst can be stably maintained.

Accordingly, the off-leakage current flowing through the first reset transistor Trst can be prevented.

Accordingly, the off-leakage current of the reset circuit RC can be prevented, so that the leakage current can be prevented from flowing into the Q2 node and Q node connected to the output terminal of the reset circuit RC, and thus, it can be free from the influence of the leakage current.

Therefore, the voltages of the Q2 node and Q node of the second scan stage SSC2 can be prevented from abnormally fluctuating due to the leakage current, so that the malfunction of the second scan stage SSC2 due to the leakage current can be prevented, and the reliability of the signal output therefrom can be improved.

Meanwhile, in this embodiment, as mentioned above, the second reset transistor Trst2 that resets the QB node can be additionally provided in the second scan stage SSC2.

This second reset transistor Trst2 can transmit the gate low voltage VGL to the QB node in response to a reset signal RSTB input thereto during a reset period, so that the QB node can be reset to a low state. Here, for convenience of explanation, the reset signal RST input to the first reset transistor Trst is referred to as a first reset signal RST, and the reset signal RSTB input to the second reset transistor Trst2 can be referred to as the second reset signal RSTB.

At this time, the second reset signal RSTB can be a signal having an opposite phase to the first reset signal RST. In this case, during the reset period, the first reset signal RST can be in a high state and the second reset signal RSTB can be in a low state, and during the reset off period, the first reset signal RST can be in a low state and the second reset signal RSTB can be in a high state.

The second reset transistor Trst2 can have, for example, a gate electrode that receives the second reset signal RSTB, a second electrode (or a drain electrode) that receives the gate low voltage VGL, and a first electrode (or a source electrode) that is connected to the QB node.

Accordingly, during the reset period, when the second reset signal RSTB in a low state (i.e., gate low voltage VGL) is applied to the second reset transistor Trst2, the second reset transistor Trst2 can be turned on, so that the gate low voltage VGL, which is the reset voltage, can be transmitted to the QB node.

In addition, during the reset off period after the reset period, the second reset signal RSTB can be switched to a high state, i.e., the gate high voltage VGH, and the second reset transistor Trst2 can be turned off.

As such, in this embodiment, the second reset transistor Trst2 to reset the QB node may be additionally provided.

In this regard, in the circuit configuration of the second scan stage SSC2 of this embodiment, similarly to the third and fourth embodiments, when the Q node is reset to a high state through the reset circuit RC, a reset of the QB node due to the reset of the Q node is not performed.

However, the second scan stage SSC2 of this embodiment can be separately provided with the second reset transistor Trst2 connected to the QB node, so that the QB node can be stably reset to a low state through the second reset transistor Trst2.

Meanwhile, in the above-described embodiments, various scan driving circuits to which the reset circuit can be applied are given as examples, and the reset circuit can be applied to various driving circuits that need the reset.

As described above, in the embodiments of the present disclosure, by adding the auxiliary transistor, which is connected in series with the reset transistor, to the reset circuit, the source electrode of the reset transistor can stably have a voltage higher than the gate low voltage during the reset off period, so that the turn-off state of the reset transistor can be stably secured.

Accordingly, the off-leakage current of the reset circuit can be prevented, so that the leakage current can be prevented from flowing into the Q node connected to the output terminal of the reset circuit, and thus it can be free from the influence of the leakage current.

Therefore, the voltage of the Q node of the stage outputting the gate signal can be prevented from abnormally fluctuating due to the leakage current, so that the malfunction of the stage due to the leakage current can be prevented, and the reliability of the signal output from it can be improved.

Furthermore, in the embodiments of the present disclosure, the reset transistor for resetting the QB node can be additionally provided. Through this reset transistor, the QB node can be stably reset to a low state.

It will be apparent to those skilled in the art that various modifications and variation can be made in the present disclosure without departing from the spirit or scope of the disclosure. Thus, it is intended that the present disclosure cover the modifications and variations of this disclosure including those of the appended claims and their equivalents.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a display panel including a pixel;
a light emitting diode and a plurality of transistors electrically connected to the light emitting diode, in the pixel; and
a gate driving circuit including a stage configured to output a gate signal to one of the plurality of transistors,
wherein the stage includes:
a pull-up transistor and a pull-down transistor, a gate electrode of the pull-up transistor and a gate electrode of the pull-down transistor respectively connected to a Q node and a QB node;
a transfer transistor connected between the Q node and a Q2 node; and
a reset circuit connected to one of the Q node or the Q2 node,
wherein the reset circuit includes an N-type reset transistor configured to receive a gate high voltage, and a P-type auxiliary transistor connected between the N-type reset transistor and the one of the Q node or the Q2 node.

2. The display apparatus of claim 1, wherein the reset transistor includes an oxide semiconductor, and a gate electrode of the reset transistor is configured to receive a reset signal.

3. The display apparatus of claim 1, wherein the auxiliary transistor includes polycrystalline silicon, and a gate electrode of the auxiliary transistor is configured to receive a gate low voltage.

4. The display apparatus of claim 1, wherein the stage further includes a first control transistor that is connected to the Q2 node, configured to receive a carry signal and has a gate electrode configured to receive a gate clock.

5. The display apparatus of claim 4, wherein the Q2 node is electrically coupled to the gate clock.

6. The display apparatus of claim 1, wherein the stage further includes a P-type second reset transistor that is connected to the QB node and is configured to receive a gate low voltage.

7. The display apparatus of claim 6, wherein a first reset signal is to be applied to the reset transistor and a second reset signal is to be applied to the second reset transistor are opposite in phase.

8. The display apparatus of claim 1, wherein the pull-up transistor, the pull-down transistor and the transfer transistor are P-type transistors including polycrystalline silicon.

9. The display apparatus of claim 4, wherein the stage further includes:
a P-type second control transistor having a gate electrode connected to the Q2 node, a source electrode configured to receive a gate high voltage, and a drain electrode connected to the QB node; and
a N-type third control transistor having a gate electrode connected to the Q node, a source electrode configured to receive a gate low voltage, and a drain electrode connected to the QB node.

10. The display apparatus of claim 1, wherein the stage further includes a Q capacitor connected between the Q node and a source electrode of the pull-up transistor.

11. The display apparatus of claim 1, wherein the stage further includes a QB capacitor connected between the QB node and a source electrode of the pull-down transistor.

12. A driving circuit, comprising:
a transistor having a source electrode or a drain electrode connected to a node; and
a reset circuit connected to the node,
wherein the reset circuit includes:
an N-type reset transistor configured to receive a gate high voltage; and
a P-type auxiliary transistor connected between the N-type reset transistor and the node.

13. The driving circuit of claim 12, wherein the reset transistor includes an oxide semiconductor, and a gate electrode of the reset transistor is configured to receive a reset signal.

14. The driving circuit of claim 12, wherein the auxiliary transistor includes polycrystalline silicon, and a gate electrode of the auxiliary transistor is configured to receive a gate low voltage.

15. The driving circuit of claim 12, further comprising a control transistor that is connected to the node and has a gate electrode configured to receive a clock signal.

16. A driving circuit, comprising:
an output portion; and
a control portion configured to control output operation of the output portion,
wherein the output portion includes a pull-up transistor and a pull-down transistor, a gate electrode of the pull-up transistor and a gate electrode of the pull-down transistor respectively connected to a Q node and a QB node, and
wherein the control portion includes a reset circuit including an N-type reset transistor configured to receive a gate high voltage, and a P-type auxiliary transistor connected between the N-type reset transistor and the Q node or a Q2 node.

17. The driving circuit of claim 16, wherein the control portion further includes a transfer transistor connected between the Q node and the Q2 node.
